(19) United States
(12) Patent Application Publication
(10) Pub. No.: US 2025/0102906 A1
(43) Pub. Date: Mar. 27, 2025

(54) ORGANOMETALLIC COMPOUND, RESIST COMPOSITION INCLUDING THE SAME AND PATTERN FORMATION METHOD USING THE RESIST COMPOSITION

(71) Applicant: Samsung Electronics Co., Ltd., Suwon-si (KR)

(72) Inventors: Jinwon JEON, Suwon-si (KR); Haengdeog KOH, Suwon-si (KR); Yoonhyun KWAK, Suwon-si (KR); Mijeong KIM, Suwon-si (KR); Sunyoung LEE, Suwon-si (KR); Changheon LEE, Suwon-si (KR); Kyuhyun IM, Suwon-si (KR); Jungha CHAE, Suwon-si (KR); Minyoung HA, Suwon-si (KR)

(73) Assignee: Samsung Electronics Co., Ltd., Suwon-si (KR)

(21) Appl. No.: 18/420,038

(22) Filed: Jan. 23, 2024

(30) Foreign Application Priority Data
Sep. 25, 2023 (KR) 10-2023-0128482

(51) Int. Cl. G03F 7/004; C07F 7/22

(52) U.S. Cl. CPC G03F 7/0042; C07F 7/2224

(57) ABSTRACT

Provided are an organometallic compound represented by one of Formulae 1-1 to 1-4, a resist composition including the same, and a pattern formation method using the resist composition:

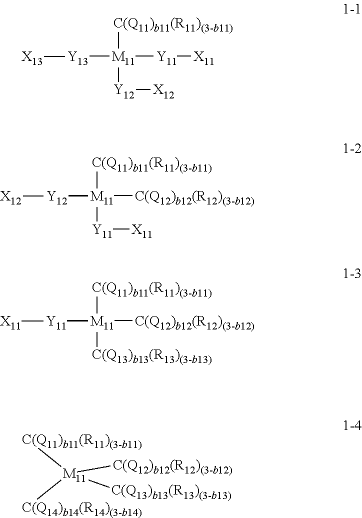

M₁₁, Q₁₁ to Q₁₄, b11 to b14, R₁₁ to R₁₄, Y₁₁ to Y₁₃, and X₁₁ to X₁₄ in Formulae 1-1 to 1-4 are as described in the specification.

### CROSS-REFERENCE TO RELATED APPLICATION

This application is based on and claims priority under 35 U.S.C. § 119 to Korean Patent Application No. 10-2023-0128482, filed on Sep. 25, 2023, in the Korean Intellectual Property Office, the disclosure of which is incorporated by reference herein in its entirety.

### BACKGROUND

### 1. Field

The disclosure relates to an organometallic compound, a resist composition including the same, and a pattern formation method using the resist composition.

### 2. Description of the Related Art

In manufacturing semiconductors, resists that undergo changes in physical properties in response to light are used to form micropatterns. Among these resists, chemically amplified resists are widely used. In the case of chemically amplified resists, an acid formed through a reaction between light and a photoacid generator reacts with a base resin again to change the solubility of the base resin with respect to a developer, thereby enabling patterning.

However, in the case of chemically amplified resists, the diffusion of the acid formed into non-exposed areas can lead to poor pattern uniformity and increased surface roughness. In an embodiment, with increasingly miniaturized semiconductor processes, it is not easy to control the diffusion of acids, resulting in the need to develop a new type of resist.

Recently, in order to overcome the limits of chemically amplified resists, attempts have been made to develop materials of which physical properties change due to exposure to light. However, the high dose required for exposure is still high.

### SUMMARY

Provided are a resist composition whose properties change even with low doses of exposure, and which provides patterns of improved resolution, and a pattern formation method using the same.

Additional aspects will be set forth in part in the description which follows and, in part, will be apparent from the description, or may be learned by practice of the presented embodiments of the disclosure.

According to an example embodiment, an organometallic compound may be represented by one of Formulae 1-1 to 1-4:

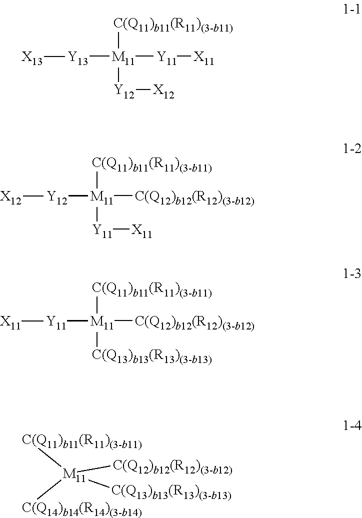

In Formulae 1-1 to 1-4,
M₁₁ may be indium (In), tin (Sn), antimony (Sb), tellurium (Te), thallium (Tl), lead (Pb), bismuth (Bi), or polonium (Po),
Q₁₁ to Q₁₄ may each independently be a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
b11 may be 2 or 3,
b12 to b14 may each independently be an integer from 0 to 3,
R₁₁ to R₁₄ may each independently be hydrogen, deuterium, a halogen, a hydroxyl group, a cyano group, a nitro group, a carboxylic acid group, a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
an adjacent two of Q₁₁ to Q₁₄ and R₁₁ to R₁₄ may optionally be bonded to each other to form a condensed ring,
Y₁₁ to Y₁₃ may each independently be O, O(C═O), S, S(C═O), NX₁₄, or N(C═O)X₁₄, and
X₁₁ to X₁₄ may each independently be: hydrogen; deuterium; or a linear, branched, or cyclic C₁-C₃₀ monovalent hydrocarbon group optionally including a hetero atom.

According to an example embodiment, a resist composition may include the organometallic compound.

According to an example embodiment, a pattern formation method may include forming a resist film by applying the resist composition on a substrate, exposing at least one portion of the resist film to high-energy rays to provide an exposed resist film, and developing the exposed resist film using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a pattern formation method according to an embodiment.

FIGS. 2A to 2C are side cross-sectional views illustrating a pattern forming method according to an embodiment;

FIGS. 3A to 3C are diagrams showing ¹H-NMR data, ¹³C-NMR data and ¹¹⁹Sn-NMR data of A-2, respectively;

FIGS. 4A to 4C are diagrams showing ¹H-NMR data, ¹³C-NMR data and ¹¹⁹Sn-NMR data of A-1, respectively;

FIGS. 5A to 5C are diagrams showing ¹H-NMR data, ¹³C-NMR data and ¹¹⁹Sn-NMR data of OM-A, respectively;

FIGS. 6A to 6C are diagrams showing ¹H-NMR data, ¹³C-NMR data and ¹¹⁹Sn-NMR data of B-2, respectively;

FIGS. 7A to 7C are diagrams showing ¹H-NMR data, ¹³C-NMR data and ¹¹⁹Sn-NMR data of B-1, respectively;

FIGS. 8A to 8C are diagrams showing ¹H-NMR data, ¹¹C-NMR data and ¹¹⁹Sn-NMR data of OM-B, respectively;

FIGS. 9A to 9E are diagrams showing changes in film thickness after development depending on doses of Examples 1-1 to 1-5, respectively;

FIG. 10A is a diagram showing the change in film thickness after development depending on the dose of Example 2-1;

FIGS. 11A to 11C are diagrams showing changes in film thickness after development depending on doses of Comparative Examples 1 to 3, respectively.

FIGS. 12A to 12E are side cross-sectional views illustrating a method of forming a patterned structure according to an embodiment; and

FIGS. 13A to 13E are side cross-sectional views illustrating a method of forming a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As the disclosure below allows for various changes and numerous embodiments, particular embodiments will be illustrated in the drawings and described in detail in the written description. However, this is not intended to limit the disclosure to particular modes of practice, and it is to be appreciated that all modifications, equivalents, and substitutes that do not depart from the spirit and technical scope of the disclosure are encompassed in the disclosure. In the following description of the disclosure, a detailed description of known functions and configurations incorporated herein will be omitted when it may obscure the subject matter of the disclosure.

Although the terms “first”, “second”, “third”, and the like may be used herein to describe various elements, these terms are only used to distinguish one element from another and the order, type, or the like of the elements are not limited thereby.

Throughout the specification, it will be understood that when one element such as layer, film, region, or plate, is referred to as being “on” another element, it may be directly on the other element or intervening elements may also be present therebetween.

An expression used in the singular encompasses the expression of the plural, unless it has a clearly different meaning in the context. In the present specification, it is to be understood that the terms such as “including” or “having,” etc., are intended to indicate the existence of the features, numbers, operations, elements, parts, components, materials, or combinations thereof disclosed in the specification, and are not intended to preclude the possibility that one or more other features, numbers, operations, elements, parts, components, materials, or combinations thereof may exist or may be added, unless otherwise stated.

Whenever a range of values is recited, the range includes all values corresponding to the range as clearly recited and also includes boundaries of the range. Accordingly, the range “X to Y” includes all values between X and Y, including X and Y.

The term “Cₓ-C_{y}” as used herein means that the number of carbon atoms constituting a substituent is in a range of x to y. For example, the term “C₁-C₆” means that the number of carbon atoms constituting a substituent is in a range of 1 to 6, and the term “C₆-C₂₀” means that the number of carbon atoms constituting a substituent is in a range of 6 to 20.

The term “monovalent hydrocarbon group” as used herein refers to a monovalent residue derived from an organic compound containing carbon and hydrogen or a derivative thereof, and examples thereof may include: linear or branched alkyl groups (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); monovalent saturated cycloaliphatic hydrocarbon groups (cycloalkyl groups) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclodecanyl group, a tetracyclododecanyl group, a tetracyclododecanylmethyl group, and a dicyclohexylmethyl group); monovalent unsaturated aliphatic hydrocarbon groups (an alkenyl group and an alkynyl group) (e.g., an allyl group); monovalent unsaturated cycloaliphatic hydrocarbon groups (cycloalkenyl groups) (e.g., 3-cyclohexenyl); aryl groups (e.g., a phenyl group, a 1-naphthyl group, and a 2-naphthyl group); arylalkyl groups (e.g., a benzyl group and a diphenylmethyl group); heteroatom-containing monovalent hydrocarbon groups (e.g., a tetrahydrofuranyl group, a methoxymethyl group, an ethoxymethyl group, a methylthiomethyl group, an acetamidemethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group); or a combination thereof. In an embodiment, because, in these groups, some hydrogen atoms may be substituted with a moiety including a hetero atom, such as oxygen, sulfur, nitrogen, or a halogen atom, or some carbon atoms may be substituted with a moiety including a hetero atom, such as oxygen, sulfur, or nitrogen, the groups may include a hydroxyl group, a cyano group, a carbonyl group, a carboxyl group, an ether bond, an ester bond, a sulfonate ester bond, a carbonate, a lactone ring, a sultone ring, a carboxylic anhydride moiety, or a haloalkyl moiety.

The term “divalent hydrocarbon group” as used herein is a divalent residue and means that any one hydrogen of the monovalent hydrocarbon group is substituted with a binding site to a neighboring atom. The divalent hydrocarbon group may include, for example, a linear or branched alkylene group, a cycloalkylene group, an alkenylene group, an alkynylene group, a cycloalkylene group, an arylene group, and those in which some carbon atoms are replaced with a hetero atom.

The term “alkyl group” as used herein refers to a linear or branched saturated aliphatic monovalent hydrocarbon group, and non-limiting examples thereof may include a methyl group, an ethyl group, a propyl group, an isobutyl group, a sec-butyl group, a tert-butyl group, a pentyl group, an iso-amyl group, and a hexyl group. The term “alkylene group” as used herein refers to a linear or branched saturated aliphatic divalent hydrocarbon group, and non-limiting examples thereof may include a methylene group, an ethylene group, a propylene group, a butylene group, and an isobutylene group.

The term “halogenated alkyl group” as used herein refers to a group in which at least one substituent of an alkyl group is substituted with a halogen, and non-limiting examples thereof may include CF₃. In this regard, the halogen atom is F, Cl, Br, or I.

The term “alkoxy group” as used herein refers to a monovalent group having the formula —OA₁₀₁ wherein A₁₀₁ is an alkyl group. Examples thereof include a methoxy group, an ethoxy group, and an isopropyloxy group.

The term “alkylthio group” as used herein refers to a monovalent group having the formula —SA₁₀₁ wherein A₁₀₁ may be an alkyl group.

The term “halogenated alkoxy group” as used herein refers to a group in which at least one hydrogen of the alkoxy group is substituted with a halogen, and non-limiting examples thereof include —OCF₃.

The term “halogenated alkylthio group” as used herein refers to a group in which at least one hydrogen of the alkylthio group is substituted with a halogen, and non-limiting examples thereof may include —SCF₃.

The term “cycloalkyl group” as used herein refers to a cyclic saturated monovalent hydrocarbon group, and examples thereof may include monocyclic groups such as a cyclopropyl group, a cyclobutyl group, a cyclopentyl group, a cyclohexyl group, and a cycloheptyl group, and polycyclic condensed groups such as a norbornyl group and an adamantyl group. The term “cycloalkylene group” as used herein refers to a cyclic saturated divalent hydrocarbon group, and non-limiting examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, and a dicyclohexylmethylene group.

The term “cycloalkoxy group” refers to a monovalent group having the formula —OA₁₀₂ wherein A₁₀₂ may be a cycloalkyl group. Examples thereof include a cyclopropoxy group and a cyclobutoxy group.

The term “cycloalkylthio group” as used herein refers to a monovalent group having the formula —SA₁₀₂ wherein A₁₀₂ may be a cycloalkyl group.

The term “heterocycloalkyl group” as used herein may refer to a group in which some carbon atoms of the cycloalkyl group may be substituted with a moiety containing a hetero atom, such as oxygen, sulfur, or nitrogen, and the heterocycloalkyl group may contain, for example, an ether bond, an ester bond, a sulfonate ester bond, a carbonate, a lactone ring, a sultone ring, or a carboxylic anhydride moiety. The term “heterocycloalkylene group” as used herein may be a group in which some carbon atoms of the cycloalkylene group are substituted with a moiety containing a hetero atom, such as oxygen, sulfur, or nitrogen.

The term “heterocycloalkoxy group” as used herein refers to a monovalent group having the formula —OA₁₀₃ wherein A₁₀₃ may be a heterocycloalkyl group.

The term “alkenyl group” as used herein refers to a linear or branched unsaturated aliphatic monovalent hydrocarbon group containing at least one carbon-carbon double bond. The term “alkenylene group” as used herein refers to a linear or branched unsaturated aliphatic divalent hydrocarbon group containing at least one carbon-carbon double bond.

The term “cycloalkenyl group” as used herein refers to a cyclic unsaturated monovalent hydrocarbon group containing at least one carbon-carbon double bond. The term “cycloalkenylene group” as used herein refers to a cyclic unsaturated divalent hydrocarbon group containing at least one carbon-carbon double bond.

The term “heterocycloalkenyl group” as used herein may be a group in which some carbon atoms of the cycloalkenylene group are substituted with a moiety containing a hetero atom, e.g., oxygen, sulfur, or nitrogen. The term “heterocycloalkenylene group” as used herein may be a group in which some carbon atoms of the cycloalkenylene group are substituted with a moiety containing a heteroatom, e.g., oxygen, sulfur, or nitrogen.

The term “alkynyl group” as used herein refers to a linear or branched unsaturated aliphatic monovalent hydrocarbon group containing at least one carbon-carbon triple bond.

The term “aryl group” as used herein refers to a monovalent group having a carbocyclic aromatic system, and non-limiting examples thereof may include a phenyl group, a naphthyl group, anthracenyl group, a phenanthrenyl group, a pyrenyl group, and a chrysenyl group. The term “arylene group” as used herein refers to a divalent group having a carbocyclic aromatic system.

The term “heteroaryl group” as used herein refers to a monovalent group having a heterocyclic aromatic system, and non-limiting examples thereof may include a pyridinyl group, a pyrimidinyl group, and a pyrazinyl group. The term “heteroarylene group” as used herein refers to a divalent group having a heterocyclic aromatic system.

The “substituent” as used herein may be: deuterium, a halogen, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;
a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group; and a combination thereof, which are unsubstituted or substituted with deuterium, a halogen atom, a hydroxyl group, a cyano group, a nitro group, a carbonyl group, a carboxylic acid group, an amino group, an ether moiety, an ester moiety, a sulfonate ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and a combination thereof.

Hereinafter, embodiments will be described in detail with reference to the accompanying drawings. In the drawings, like reference numerals denote like elements or components having substantially same functions, and duplicate descriptions will be omitted. In the drawings, thicknesses of various layers and regions may be enlarged for clarity. In the drawings, for convenience of explanation, thicknesses of some layers and regions are exaggerated for clarity. Meanwhile, it should be understood that embodiments described hereinafter are merely for illustrative purposes various changes in form from the embodiments.

### [Organometallic Compounds]

A organometallic compound according to embodiments may be represented by any of Formulae 1-1 to 1-4:

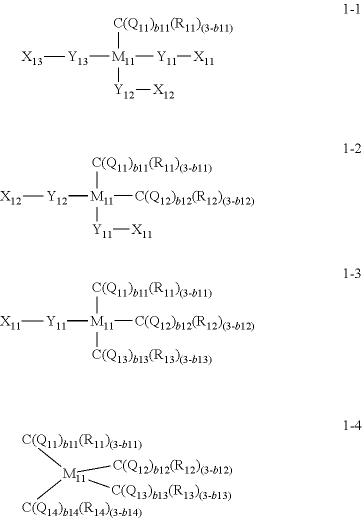

wherein, in Formulae 1-1 to 1-4,
M₁₁ may be indium (In), tin (Sn), antimony (Sb), tellurium (Te), thallium (Tl), lead (Pb), bismuth (Bi), or polonium (Po),
Q₁₁ to Q₁₄ may each independently be a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
b11 may be 2 or 3,
b12 to b14 may each independently be an integer from 0 to 3,
R₁₁ to R₁₄ may each independently be hydrogen, deuterium, a halogen, a hydroxyl group, a cyano group, a nitro group, a carboxylic acid group, a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
an adjacent two of Q₁₁ to Q₁₄ and R₁₁ to R₁₄ may optionally be bonded to each other to form a condensed ring,
Y₁₁ to Y₁₃ may each independently be O, O(C═O), S, S(C═O), NX₁₄, or N(C═O)X₁₄, and
X₁₁ to X₁₄ may each independently be: hydrogen; deuterium; or a linear, branched, or cyclic C₁-C₃₀ monovalent hydrocarbon group optionally including a hetero atom.

The molecular weight of the organometallic compound may be 3000 g/mol or less. In an embodiment, the molecular weight of the organometallic compound may be 2000 g/mol or less.

The bond dissociation energy (calculated value) of the bond between M₁ᵣ and C of the organometallic compound may be 30 kcal/mol or less. Although not limited to a specific theory, b11 of Q₁₁ bound to C may stabilize radicals generated when the bond between M₁₁ and C is broken down. Accordingly, the bond dissociation energy of the bond between M₁₁ and C of the organometallic compound may be lowered. In particular, since the double or triple bond contained in Q₁₁ is directly bonded to the carbon (C) connected to M₁₁, the radical generated when the bond between M₁₁ and C is broken down, may be resonance-stabilized by Q₁₁.

For example, M₁₁ in Formulae 1-1 to 1-4 may be In, Sn, or Sb. In an embodiment, M₁₁ in Formulae 1-1 to 1-4 may be Sn.

For example, Q₁₁ to Q₁₄ in Formulae 1-1 to 1-4 may each independently be selected from a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, and a C₁-C₃₀ heteroaryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, an C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In an embodiment, Q₁₁ to Q₁₄ in Formulae 1-1 to 1-4 may each independently be selected from a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, an C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In an embodiment, Q₁₁ to Q₁₄ in Formulae 1-1 to 1-4 may each independently be selected from an ethenyl group, a cyclopentenyl group, a cyclohexenyl group, a cyclopentadienyl group, a cyclohexadienyl group, an ethynyl group, a phenyl group, and a naphthyl group, each unsubstituted or substituted with deuterium, a halogen, a hydroxyl group, a cyano group, a nitro group, a C₁-C₁₀ alkyl group of a C₁-C₁₀ halogenated alkyl group, a C₁-C₁₀ alkoxy group, a C₁-C₁₀ alkylthio group, a C₁-C₁₀ halogenated alkoxy group, a C₁-C₁₀ halogenated alkylthio group, a C₃-C₁₀ cycloalkyl group, a C₃-C₁₀ cycloalkoxy group, a C₃-C₁₀ cycloalkylthio group, a phenyl group, a naphthyl group, a phenyloxy group, a naphthyloxy group, a phenylthio group, a naphthylthio group, or a combination thereof.

For example, in Formulae 1-1 to 1-4, b11 may be 2 or 3; b12 may be 2 or 3; b13 may be 2 or 3; or b14 may be 2 or 3. In some embodiments, b11 to b14 in Formulae 1-1 to 1-4 may each independently be 2 or 3.

For example, R₁₁ to R₁₄ in Formulae 1-1 to 1-4 may each independently be selected from: hydrogen; deuterium; a halogen; a hydroxyl group; a cyano group; a nitro group; a carboxylic acid group; and a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, and a C₁-C₃₀ heteroaryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In an embodiment, R₁₁ to R₁₄ in Formulae 1-1 to 1-4 may each independently be selected from: hydrogen; deuterium; a halogen; a hydroxyl group; a cyano group; a nitro group; a carboxylic acid group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

In some embodiments, R₁₁ to R₁₄ in Formulae 1-1 to 1-4 may each independently be: hydrogen; deuterium; a halogen; a hydroxyl group; a cyano group; a nitro group; a carboxylic acid group; and a methyl group, an ethyl group, an n-propyl group, an iso-propyl group, an n-butyl group, a sec-butyl group, an iso-a butyl group, a tert-butyl group, a cyclopentyl group, a cyclohexyl group, an ethenyl group, a cyclopentenyl group, a cyclohexenyl group, a cyclopentadienyl group, a cyclohexadienyl group, an ethynyl group, a phenyl group, and a naphthyl group, each unsubstituted or substituted with deuterium, a halogen, a hydroxyl group, a cyano group, a nitro group, a C₁-C₁₀ alkyl group, a C₁-C₁₀ halogenated alkyl group, a C₁-C₁₀ alkoxy group, a C₁-C₁₀ alkylthio group, a C₁-C₁₀ halogenated alkoxy group, a C₁-C₁₀ halogenated alkylthio group, a C₃-C₁₀ cycloalkyl group, a C₃-C₁₀ cycloalkoxy group, a C₃-C₁₀ cycloalkylthio group, a phenyl group, a naphthyl group, a phenyloxy group, a naphthyloxy group, a phenylthio group, a naphthylthio group, or a combination thereof.

In an embodiment, b11 in Formulae 1-1 to 1-4 may be 2. In some embodiments, b11 to b14 in Formulae 1-1 to 1-4 may each independently be 2.

In an embodiment, regarding Formulae 1-1 to 1-4, *—C(Q₁₁)_{b11}(R₁₁)_{(3-b11)} may be represented by one of Formulae 2-11 to 2-14; *—C(Q₁₂)_{b12}(R₁₂)_{(3-b12)} may be represented by one of Formulae 2-21 to 2-30; *—C(Q₁₃)_{b13}(R₁₃)_{(3-b13)} may be represented by one of Formulae 2-31 to 2-40; and *—C(Q₁₄)_{b14}(R₁₄)_{(3-b14)} may be represented by one of Formulae 2-41 to 2-50:

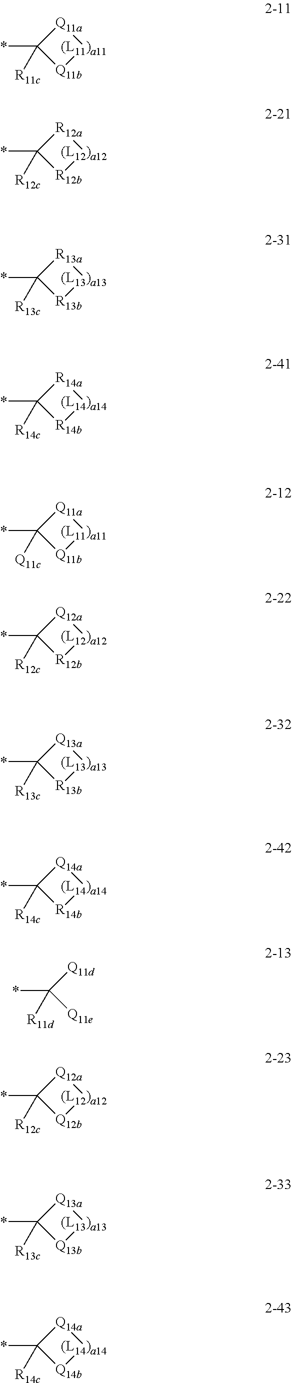

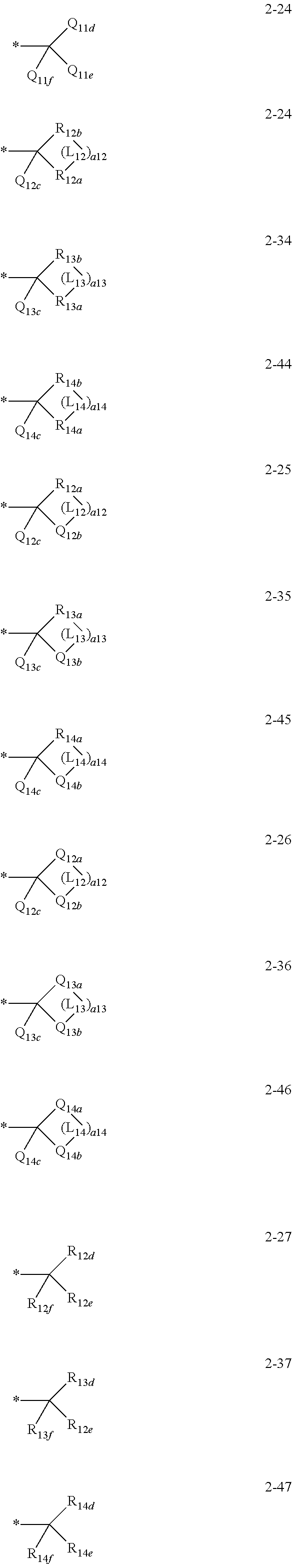

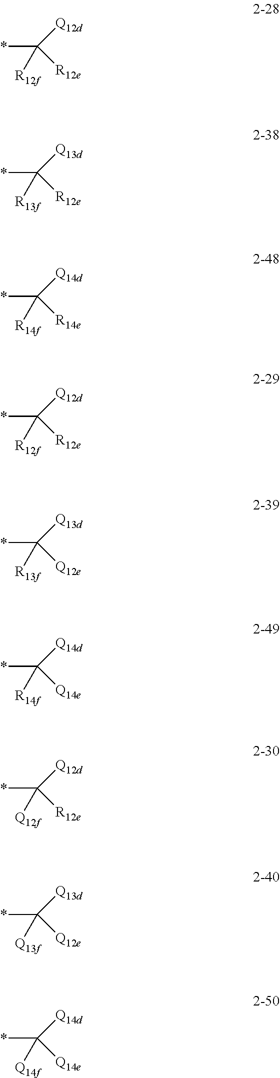

Regarding Formulae 2-11 to 2-14 and 2-21 to 2-50,
Q₁₁ₐ to Q_{11f}, Q₁₂ₐ to Q_{12f}, Q₁₃ₐ to Q_{13f} and Q₁₄ₐ to Q_{14f} may each be understood by referring to the description provided in connection with Q₁₁ in Formulae 1-1 to 1-4,
R_{11c}, R_{11d}, R₁₂ₐ to R_{12f}, R₁₃ₐ to R_{13f} and R₁₄ₐ to R_{14f} may each be understood by referring to the description provided in connection with R₁₁ in Formulae 1-1 to 1-4.

L₁₁ to L₁₄ may each independently be a single bond, O, S, a C₁-C₁₀ alkylene group, or a C₂-C₁₀ alkenylene group,
a11 to a14 may each independently be an integer from 1 to 3, and
* is a binding site with an adjacent atom.

For example, L₁₁ to L₁₄ in Formulae 2-11, 2-12, 2-21 to 2-26, 2-31 to 2-36, and 2-41 to 2-46 may each independently be a single bond or O.

For example, a11 to a14 in Formulae 2-11, 2-12, 2-21 to 2-26, 2-31 to 2-36, and 2-41 to 2-46 may each independently be 1.

For example, Q₁₁ₐ, Q_{11b}, Q₁₂ₐ, Q_{12b}, Q₁₃ₐ, Q_{13b}, Q₁₄ₐ, Q_{14b}, R₁₂ₐ, R_{12b}, R₁₃ₐ, R_{13b}, R₁₄ₐ, and R_{14b} in Formulae 2-11 to 2-14 and 2-21 to 2-50 may each independently be a substituted or unsubstituted C₃-C₃₀ cycloalkenyl group, a substituted or unsubstituted C₃-C₃₀ heterocycloalkenyl group, a substituted or unsubstituted C₆-C₃₀ aryl group, or a substituted or unsubstituted C₁-C₃₀ heteroaryl group.

In an embodiment, *—C(Q₁₁)_{b11}(R₁₁)_{(3-b11)} may be represented by one of Formulae 3-11 to 3-14; *—C(Q₁₂)_{b12}(R₁₂)_{(3-b12)} may be represented by one of Formulae 3-21 to 3-24; *—C(Q₁₃)_{b13}(R₁₃)_{(3-b13)} may be represented by one of Formulae 3-31 to 3-34; and *—C(Q₁₄)_{b14}(R₁₄)_{(3-b14)} may be represented by one of Formulae 3-41 to 3-44:

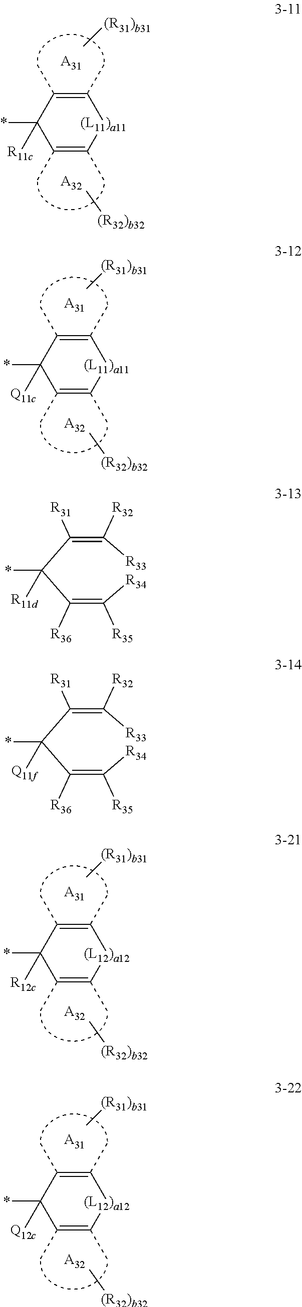

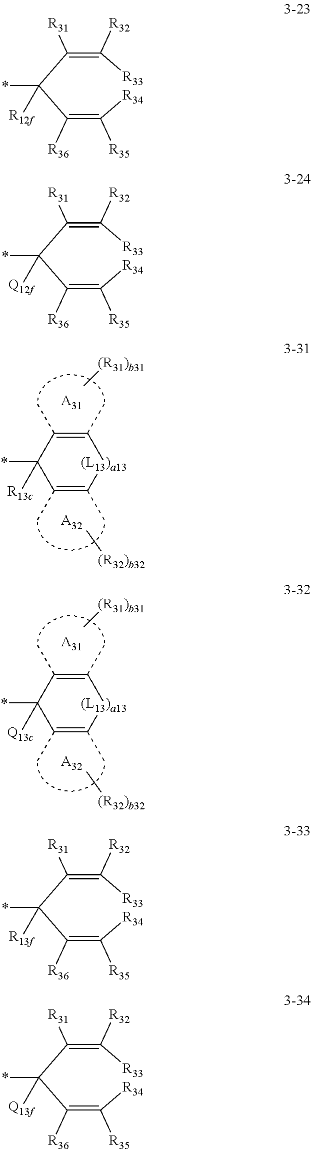

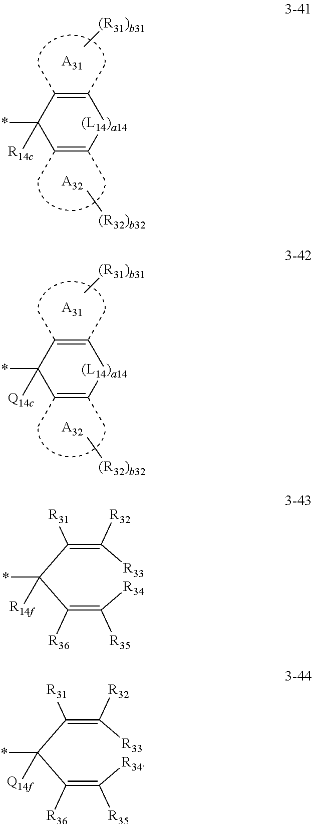

In Formulae 3-11 to 3-14, 3-21 to 3-24, 3-31 to 3-34, and 3-41 to 3-44,
Q_{11c}, Q_{11f}, Q_{12c}, Q_{12f}, Q_{13c}, Q_{13f}, Q_{14c} and Q_{14f} may each be understood by referring to the description provided in connection with Q₁₁ in Formulae 1-1 to 1-4.

R_{11c}, R_{11d}, R_{12c}, R_{12f}, R_{13c}, R_{13f}, R_{14c}, and R_{14f} may each be understood by referring to the description provided in connection with R₁₁ in Formulae 1-1 to 1-4.

L₁ to L₁₄ may each independently be a single bond, O, S, a C₁-C₁₀ alkylene group, or a C₂-C₁₀ alkenylene group,
a11 to a14 may each independently be an integer from 1 to 3,
A₃₁ and A₃₂ may each independently be a C₃-C₂₀ cycloalkenyl group, a C₃-C₂₀ heterocycloalkenyl group, a C₆-C₂₀ aryl group, or a C₁-C₂₀ heteroaryl group,
R₃₁ to R₃₆ may each independently be deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₁₀ alkyl group, a C₁-C₁₀ halogenated alkyl group, a C₁-C₁₀ alkoxy group, a C₁-C₁₀ alkylthio group, a C₁-C₁₀ halogenated alkoxy group, a C₁-C₁₀ halogenated alkylthio group, a C₃-C₁₀ cycloalkyl group, a C₃-C₁₀ cycloalkoxy group, a C₃-C₁₀ cycloalkylthio group, a C₆-C₁₀ aryl group, a C₁-C₁₀ heteroaryl group, a C₆-C₁₀ aryloxy group, a C₆-C₁₀ arylthio group, a C₁-C₁₀ heteroaryloxy group, or a C₁-C₁₀ heteroarylthio group,
b31 and b32 may each independently be an integer from 1 to 8, and
* is a binding site with an adjacent atom.

For example, L₁₁ to L₁₄ in Formulae 3-11 to 3-14, 3-21 to 3-24, 3-31 to 3-34 and 3-41 to 3-44 may each independently be a single bond or O.

For example, a11 to a14 in Formulae 3-11 to 3-14, 3-21 to 3-24, 3-31 to 3-34, and 3-41 to 3-44 may each independently be 1.

For example, A₃₁ and A₃₂ in Formulae 3-11 to 3-14, 3-21 to 3-24, 3-31 to 3-34, and 3-41 to 3-44 may each independently be a cyclopentenyl group, a cyclopentadienyl group, a cyclohexenyl group, a cyclohexadienyl group, a phenyl group, or a naphthyl group.

For example, Y₁₁ to Y₁₃ in Formulae 1-1 to 1-4 may each independently be O, O(C═O), S, or S(C═O).

For example, X₁₁ to X₁₄ in Formulae 1-1 to 1-4 may each independently be: hydrogen; deuterium; and a C₁-C₂₀ alkyl group, a C₁-C₂₀ halogenated alkyl group, a C₃-C₂₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₂₀ aryl group, and a C₁-C₂₀ heteroaryl group, each unsubstituted or substituted with deuterium, a halogen, a hydroxy group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, or a combination thereof.

In an embodiment, X₁₁ to X₁₄ in Formulae 1-1 to 1-4 may each independently be: hydrogen; deuterium; and a C₁-C₂₀ alkyl group, a C₁-C₂₀ halogenated alkyl group, a C₃-C₂₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₂₀ aryl group, and a C₁-C₂₀ heteroaryl group, each unsubstituted or substituted with deuterium, a halogen, a hydroxyl group, an amino group, a carboxylic acid group, an ester moiety, an ester moiety, a sulfonic acid ester moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or a combination thereof.

In an embodiment, X₁₁ to X₁₄ in Formulae 1-1 to 1-4 may each independently be: hydrogen; deuterium; and a C₁-C₂₀ alkyl group, a C₃-C₂₀ cycloalkyl group, a C₂-C₃₀ alkenyl group, a C₃-C₃₀ cycloalkenyl group, a C₂-C₃₀ alkynyl group, and a C₆-C₂₀ aryl group, each unsubstituted or substituted with deuterium, a halogen, a methyl group, an ethyl group, a phenyl group, a naphthyl group, or a combination thereof.

In some embodiments, X₁₁ to X₁₄ in Formulae 1-1 to 1-4 may each independently be: hydrogen; deuterium; and a methyl group, an ethyl group, an n-propyl group, an iso-propyl group, an n-butyl group, a sec-butyl group, an iso-a butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group, and a naphthyl group, each unsubstituted or substituted with deuterium, a halogen, a methyl group, an ethyl group, a phenyl group, a naphthyl group, or a combination thereof.

In an embodiment, the organometallic compound may be represented by Formula 1-2, *—C(Q₁₁)_{b11}(R₁₁)_{(3-b11)} may be represented by one of Formulae 3-11 and 3-13; and *—C(Q₁₂)_{b12}(R₁₂)_{(3-b12)} may be represented by one of Formulae 3-21 and 3-23.

In an embodiment, the organometallic compound represented by one of Formulae 1-1 to 1-4 may be selected from Group I:

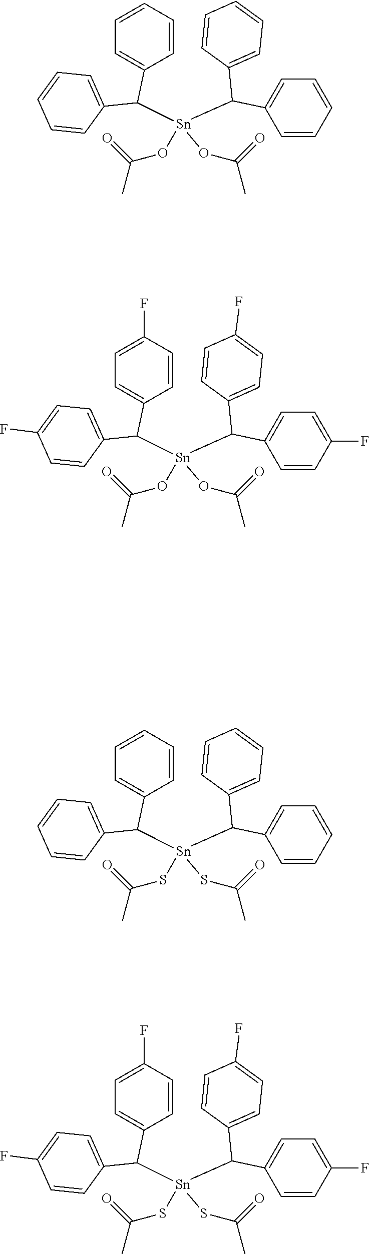 [SMILES: CC(=O)[O][Sn]([O]C(C)=O)([CH](c1ccccc1)c1ccccc1)[CH](c1ccccc1)c1ccccc1 ; CC(=O)[O][Sn]([O]C(C)=O)([CH](c1ccc(F)cc1)c1ccc(F)cc1)[CH](c1ccc(F)cc1)c1ccc(F)cc1 ; CC(=O)[S][Sn]([S]C(C)=O)([CH](c1ccccc1)c1ccccc1)[CH](c1ccccc1)c1ccccc1 ; CC(=O)[S][Sn]([S]C(C)=O)([CH](c1ccc(F)cc1)c1ccc(F)cc1)[CH](c1ccc(F)cc1)c1ccc(F)cc1]

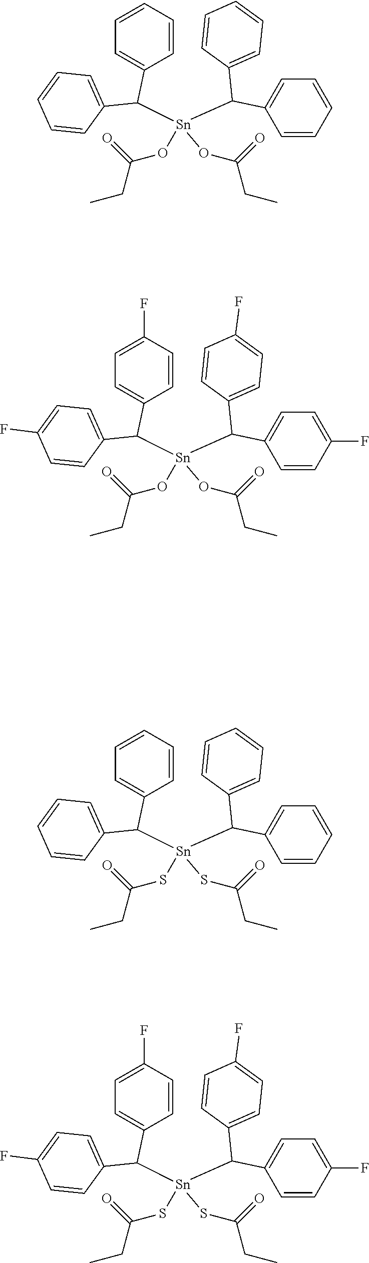 [SMILES: CCC(=O)[O][Sn]([O]C(=O)CC)([CH](c1ccccc1)c1ccccc1)[CH](c1ccccc1)c1ccccc1 ; CCC(=O)[O][Sn]([O]C(=O)CC)([CH](c1ccc(F)cc1)c1ccc(F)cc1)[CH](c1ccc(F)cc1)c1ccc(F)cc1 ; CCC(=O)[S][Sn]([S]C(=O)CC)([CH](c1ccccc1)c1ccccc1)[CH](c1ccccc1)c1ccccc1 ; CCC(=O)[S][Sn]([S]C(=O)CC)([CH](c1ccc(F)cc1)c1ccc(F)cc1)[CH](c1ccc(F)cc1)c1ccc(F)cc1]

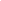

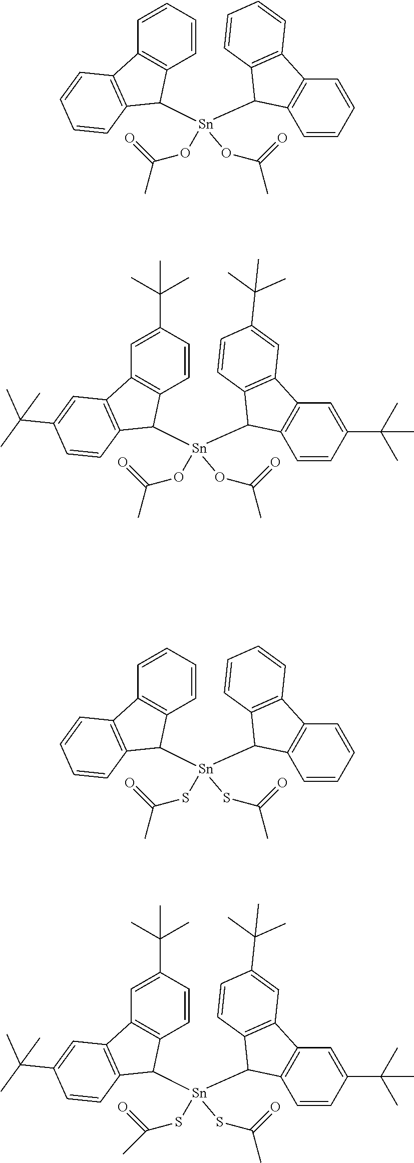

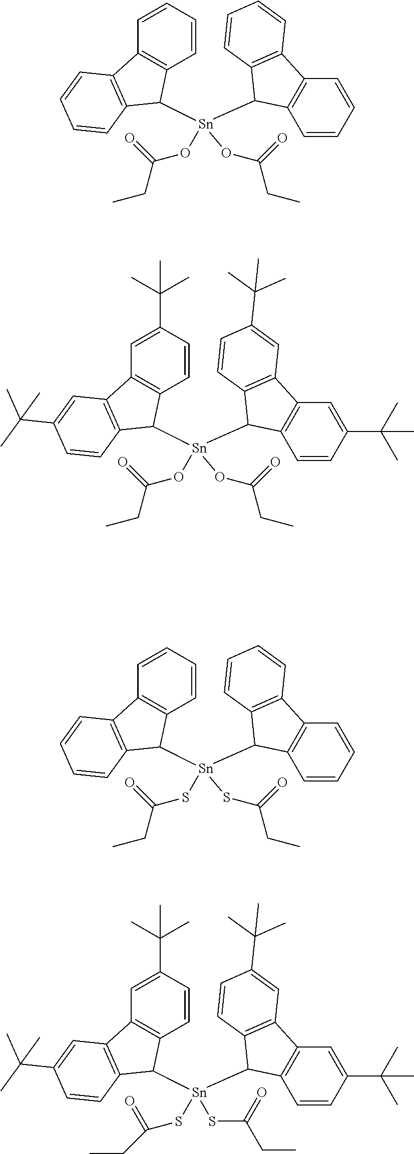

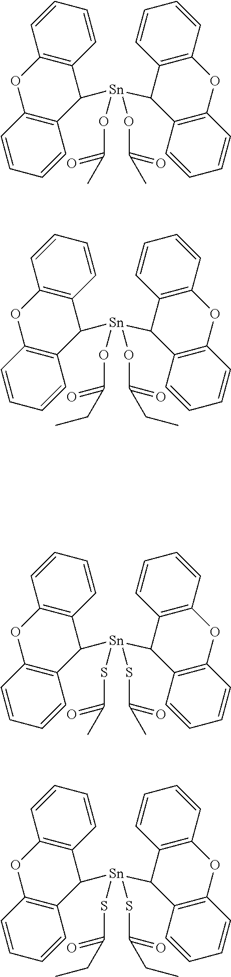 [SMILES: CC(=O)[O][Sn]([O]C(C)=O)([CH]1c2ccccc2Oc2ccccc21)[CH]1c2ccccc2Oc2ccccc21 ; CCC(=O)[O][Sn]([O]C(=O)CC)([CH]1c2ccccc2Oc2ccccc21)[CH]1c2ccccc2Oc2ccccc21 ; CC(=O)[S][Sn]([S]C(C)=O)([CH]1c2ccccc2Oc2ccccc21)[CH]1c2ccccc2Oc2ccccc21 ; CCC(=O)[S][Sn]([S]C(=O)CC)([CH]1c2ccccc2Oc2ccccc21)[CH]1c2ccccc2Oc2ccccc21]

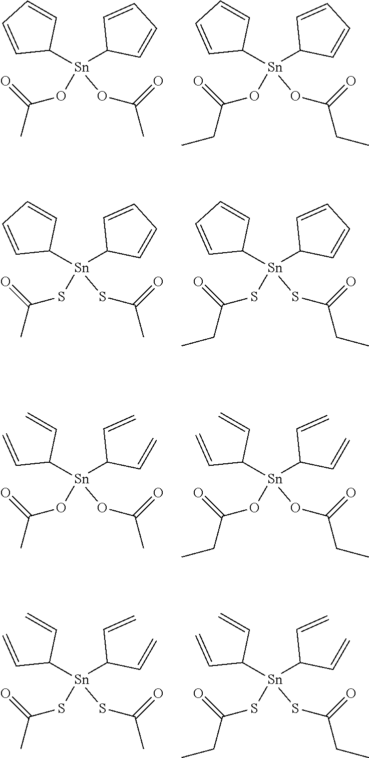

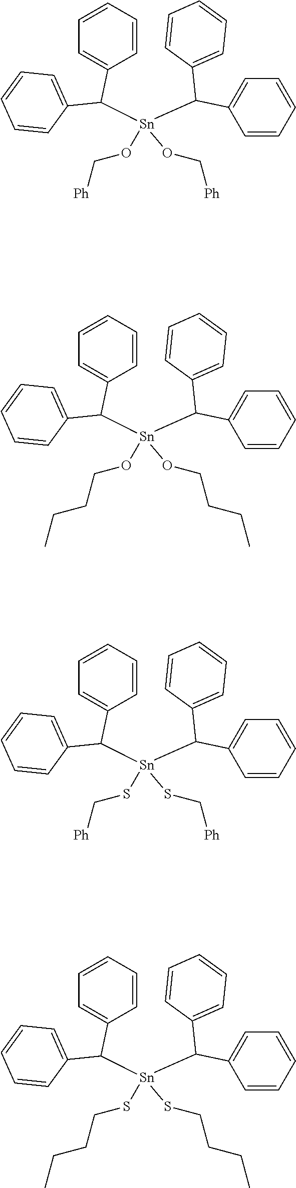 [SMILES: c1ccc(C[O][Sn]([O]Cc2ccccc2)([CH](c2ccccc2)c2ccccc2)[CH](c2ccccc2)c2ccccc2)cc1 ; CCCC[O][Sn]([O]CCCC)([CH](c1ccccc1)c1ccccc1)[CH](c1ccccc1)c1ccccc1 ; c1ccc(C[S][Sn]([S]Cc2ccccc2)([CH](c2ccccc2)c2ccccc2)[CH](c2ccccc2)c2ccccc2)cc1 ; CCCC[S][Sn]([S]CCCC)([CH](c1ccccc1)c1ccccc1)[CH](c1ccccc1)c1ccccc1]

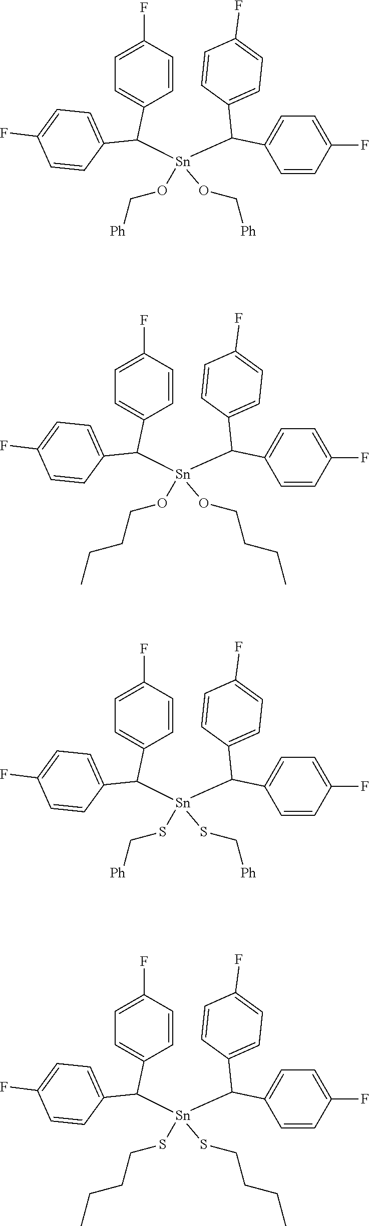 [SMILES: Fc1ccc([CH](c2ccc(F)cc2)[Sn]([O]Cc2ccccc2)([O]Cc2ccccc2)[CH](c2ccc(F)cc2)c2ccc(F)cc2)cc1 ; CCCC[O][Sn]([O]CCCC)([CH](c1ccc(F)cc1)c1ccc(F)cc1)[CH](c1ccc(F)cc1)c1ccc(F)cc1 ; Fc1ccc([CH](c2ccc(F)cc2)[Sn]([S]Cc2ccccc2)([S]Cc2ccccc2)[CH](c2ccc(F)cc2)c2ccc(F)cc2)cc1 ; CCCC[S][Sn]([S]CCCC)([CH](c1ccc(F)cc1)c1ccc(F)cc1)[CH](c1ccc(F)cc1)c1ccc(F)cc1]

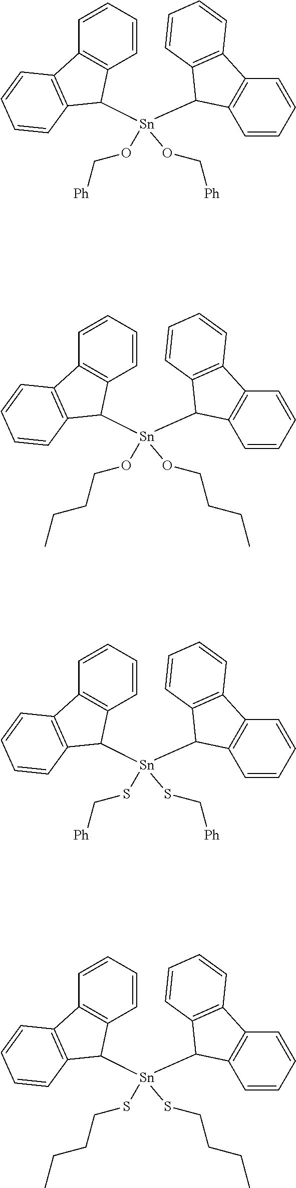 [SMILES: c1ccc(C[O][Sn]([O]Cc2ccccc2)([CH]2c3ccccc3-c3ccccc32)[CH]2c3ccccc3-c3ccccc32)cc1 ; CCCC[O][Sn]([O]CCCC)([CH]1c2ccccc2-c2ccccc21)[CH]1c2ccccc2-c2ccccc21 ; c1ccc(C[S][Sn]([S]Cc2ccccc2)([CH]2c3ccccc3-c3ccccc32)[CH]2c3ccccc3-c3ccccc32)cc1 ; CCCC[S][Sn]([S]CCCC)([CH]1c2ccccc2-c2ccccc21)[CH]1c2ccccc2-c2ccccc21]

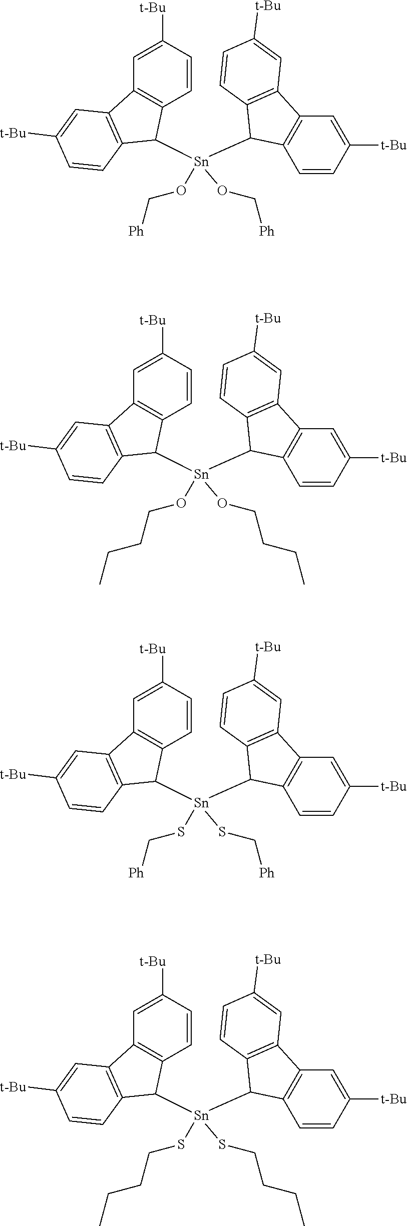 [SMILES: CC(C)(C)c1ccc2c(c1)-c1cc(C(C)(C)C)ccc1[CH]2[Sn]([O]Cc1ccccc1)([O]Cc1ccccc1)[CH]1c2ccc(C(C)(C)C)cc2-c2cc(C(C)(C)C)ccc21 ; CCCC[O][Sn]([O]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21 ; CC(C)(C)c1ccc2c(c1)-c1cc(C(C)(C)C)ccc1[CH]2[Sn]([S]Cc1ccccc1)([S]Cc1ccccc1)[CH]1c2ccc(C(C)(C)C)cc2-c2cc(C(C)(C)C)ccc21 ; CCCC[S][Sn]([S]CCCC)([CH]1c2ccc(C(C)(C)C)cc2-c2cc(C(C)(C)C)ccc21)[CH]1c2ccc(C(C)(C)C)cc2-c2cc(C(C)(C)C)ccc21]

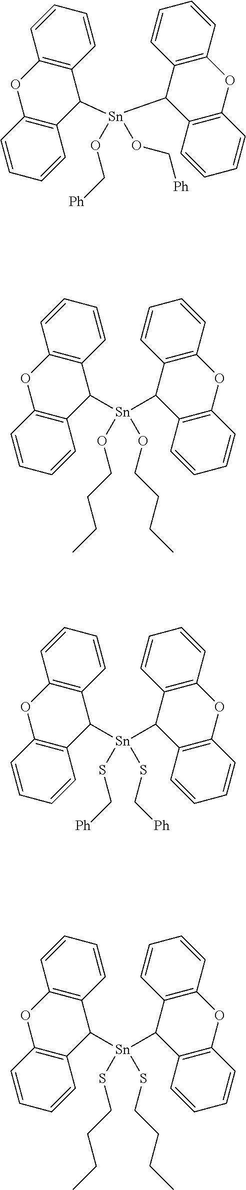 [SMILES: c1ccc(C[O][Sn]([O]Cc2ccccc2)([CH]2c3ccccc3Oc3ccccc32)[CH]2c3ccccc3Oc3ccccc32)cc1 ; CCCC[O][Sn]([O]CCCC)([CH]1c2ccccc2Oc2ccccc21)[CH]1c2ccccc2Oc2ccccc21 ; c1ccc(C[S][Sn]([S]Cc2ccccc2)([CH]2c3ccccc3Oc3ccccc32)[CH]2c3ccccc3Oc3ccccc32)cc1 ; CCCC[S][Sn]([S]CCCC)([CH]1c2ccccc2Oc2ccccc21)[CH]1c2ccccc2Oc2ccccc21]

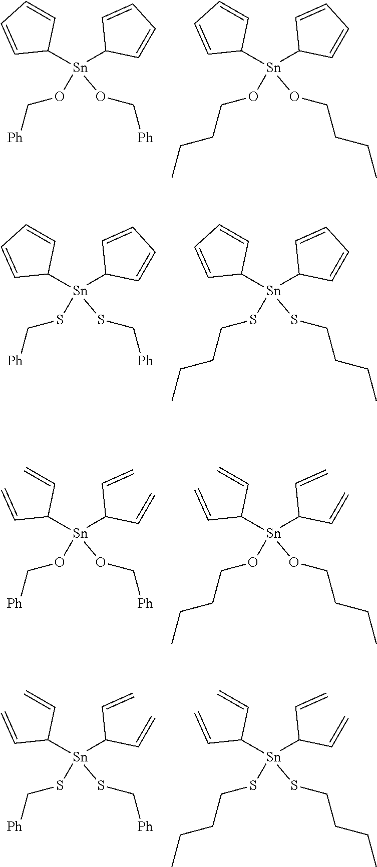

Although not limited to any particular theory, the organometallic compound may be capable of forming radicals by heat and/or high-energy radiation. In an embodiment, a radical may be formed from the M¹¹-carbon bond of the organometallic compound, and optionally in an atmosphere where water is present, the radical may react to form a chemical bond between organometallic compounds. Accordingly, the physical properties of the organometallic compound, for example, the solubility thereof with respect to a developer, may change.

In particular, the organometallic compound represented by one of Formulae 1-1 to 1-4 necessarily includes at least two Q₁₁, so that radical stability may be improved, and accordingly, the bond dissociation energy of the M₁₁-carbon bond may be lowered, and the sensitivity thereof to energy rays, for example, EUV, may be improved.

For some of the organometallic compounds represented by one of Formulae 1-1 to 1-4, the enthalpy change value by balanced homolysis of the Sn—C bond was calculated using density functional theory (DFT) calculation. Based on the obtained result, the bond dissociation energy of the Sn—C bond is defined and listed in Table 1 below.

TABLE 1

| | Bond dissociation energy |
|---|---|
| Compound No. | (kcal/mol) |
| 1 (OM-A) | 17.98 |
| 2 | 27.21 |
| 3 | 21.64 |
| 4 | 23.56 |
| 5 (OM-B) | 24.63 |
| C-1 | 40.95 |
| C-2 | 39.94 |
| C-3 | 44.31 |

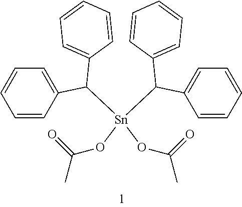 [SMILES: CC(=O)[O][Sn]([O]C(C)=O)([CH](c1ccccc1)c1ccccc1)[CH](c1ccccc1)c1ccccc1]

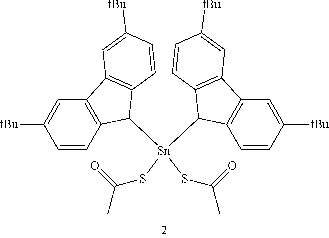 [SMILES: CC(=O)[S][Sn]([S]C(C)=O)([CH]1c2ccc(C(C)(C)C)cc2-c2cc(C(C)(C)C)ccc21)[CH]1c2ccc(C(C)(C)C)cc2-c2cc(C(C)(C)C)ccc21]

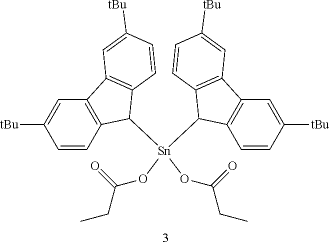 [SMILES: CCC(=O)[O][Sn]([O]C(=O)CC)([CH]1c2ccc(C(C)(C)C)cc2-c2cc(C(C)(C)C)ccc21)[CH]1c2ccc(C(C)(C)C)cc2-c2cc(C(C)(C)C)ccc21]

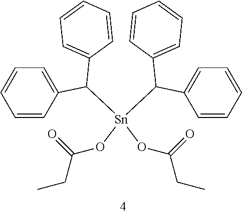 [SMILES: CCC(=O)[O][Sn]([O]C(=O)CC)([CH](c1ccccc1)c1ccccc1)[CH](c1ccccc1)c1ccccc1]

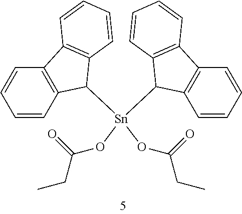 [SMILES: CCC(=O)[O][Sn]([O]C(=O)CC)([CH]1c2ccccc2-c2ccccc21)[CH]1c2ccccc2-c2ccccc21]

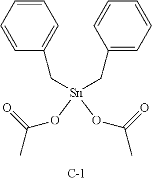

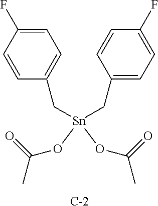

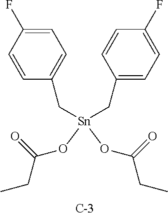

The organometallic compound may be prepared by any suitable method.

The structure (composition) of the organometallic compound may be identified through FT-IR analysis, NMR analysis, X-ray fluorescence (XRF) analysis, mass spectrometry, ultra violate (UV) analysis, single crystal X-ray structure analysis, powder X-ray diffraction (PXRD) analysis, liquid chromatography (LC), size exclusion chromatography (SEC) analysis, thermal analysis, etc. The detailed confirmation method is as described in Examples.

### [Resist Composition]

According to an aspect of the disclosure, a resist composition includes the organometallic compound. The resist composition may have improved photosensitivity and/or storage stability properties.

Exposure to high-energy rays changes solubility of the resist composition in a developer. The resist composition may be a negative resist composition. That is, a non-exposed portion of the resist film is dissolved and removed to form a negative resist pattern.

In an embodiment, the resist composition according to an embodiment may be: for an alkaline developing process using an alkaline developer for developing treatment when forming a resist pattern; or for a solvent developing process using a developer containing an organic solvent for the developing treatment (hereinafter, also referred to as an organic developer).

The resist composition may be non-chemically amplified. In this case, a photoacid generator substantially may not be included.

Since the physical properties of the organometallic compound change by exposure, the resist composition may not substantially include compounds with a molecular weight of 1,000 or more other than the organometallic compound.

The amount of the organometallic compound in the resist composition may be, based on 100 parts by weight of the organometallic compound, from about 0.1 parts by weight to about 100 parts by weight, for example, 0.2 parts by weight or more, 0.5 parts by weight or more, 1 part by weight or more, or 2 parts by weight or more, and 90 parts by weight or less, or 80 parts by weight or less. Within these ranges, chemical bonds between organometallic compounds are sufficiently formed while side reactions are suppressed, thereby providing a resist composition with improved sensitivity and/or resolution.

### <Organic Solvent>

The resist composition may further include an organic solvent.

The organic solvent included in the resist composition is not particularly limited, as long as the organometallic compound and any component contained therein as needed may be dissolved or dispersed therein. The organic solvent may be used alone or any combination of two or more different organic solvents may also be used.

In an embodiment, the organic solvent may include a protic organic solvent, an aprotic organic solvent or a combination thereof.

In some embodiments, the organic solvent may be a mixture including an aprotic organic solvent and a protic organic solvent.

Since the resist composition may include substantially no water, the organic solvent may not include water. In an embodiment, the resist composition may include not more than 3 wt % water, and the organic solvent may include not more than 3 wt % water.

Examples of the organic solvent may include alcohol-based solvents, ether-based solvents, ketone-based solvents, amide-based solvents, ester-based solvents, sulfoxide-based solvents, and hydrocarbon-based solvents.

In some embodiments, examples of the alcohol-based solvents may include: a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxy butanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonylalcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, and diacetone alcohol; a polyalcohol-based solvent such as ethyleneglycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethyleneglycol, dipropyleneglycol, triethylene glycol, and tripropylene glycol; and a polyalcohol-containing ether-based solvent such as ethyleneglycol monomethylether, ethyleneglycol monoethylether, ethyleneglycol monopropylether, ethyleneglycol monobutylether, ethyleneglycol monohexylether, ethyleneglycol monophenylether, ethyleneglycol mono-2-ethylbutylether, diethyleneglycol monomethylether, diethyleneglycol monoethylether, diethyleneglycol monopropylether, diethyleneglycol monobutylether, diethyleneglycol monohexyl ether, propylene glycol monomethylether, propylene glycol monoethylether propylene glycol monopropylether, propylene glycol monobutylether, dipropyleneglycol monomethylether, dipropyleneglycol monoethylether, and dipropyleneglycol monopropylether.

Examples of the ether-based solvent include: dialkyl ether-based solvents such as diethyl ether, dipropyl ether, dibutyl ether, diethylene glycol dimethyl ether, and dipropylene glycol dimethyl ether; cyclic ether solvents such as tetrahydrofuran and tetrahydropyran; and aromatic ring-containing ether-based solvents such as diphenyl ether and anisole.

Examples of the ketone-based solvents may include: a chain-shaped ketone-based solvent such as acetone, methylethylketone, methyl-n-propylketone, methyl-n-butylketone, methyl-n-pentylketone, diethylketone, methylisobutylketone, 2-heptanone, ethyl-n-butylketone, methyl-n-hexylketone, diisobutylketone, and trimethylnonanone; a cyclic ketone-based solvent such as cyclopentanone, cyclo hexanone, cycloheptanone, cyclooctanone, and methylcyclohexanone; and 2,4-pentanedione, acetonylacetone, and acetphenone.

Examples of the amide-based solvents may include: a cyclic amide-based solvent such as N,N′-dimethylimidazolidinone and N-methyl-2-pyrrolidone; and a chain-shaped amide-based solvent such as N-methylformamide, N,N-dimethylformamide, N,N-diethylformamide, acetamide, N-methylacetamide, N,N-dimethylacetamide, and N-methylpropyoneamide.

Examples of the ester-based solvents include: an acetate ester-based solvent such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, and n-nonyl acetate; a polyalcohol-containing ethercarboxylate-based solvent such as ethyleneglycol monomethylether acetate, ethyleneglycol monoethylether acetate, diethyleneglycol monomethylether acetate, diethyleneglycol monoethylether acetate, diethyleneglycol mono-n-butyl ether acetate, propylene glycol monomethylether acetate (PGMEA), propylene glycol monoethylether acetate, propylene glycol monopropylether acetate, propylene glycol monobutylether acetate, dipropylene glycol monomethylether acetate, and dipropylene glycol monoethylether acetate; a lactone-based solvent such as γ-butyrolactone and 6-valerolactone; a carbonate-based solvent such as dimethyl carbonate, diethyl carbonate, ethylene carbonate, and propylene carbonate; a lactate ester-based solvent such as methyl lactate, ethyl lactate, n-butyl lactate, and n-amyl lactate; and glycole diacetate, methoxytriglycol acetate, ethyl propionate, n-butyl propionate, isoamyl propionate, diethyloxalate, di-n-butyloxalate, methyl acetoacetate, ethyl acetoacetate, diethyl malonate, dimethyl phthalate, and diethyl phthalate.

Examples of the sulfoxide-based solvents may include dimethyl sulfoxide and diethyl sulfoxide.

Examples of the hydrocarbon-based solvents include: an aliphatic hydrocarbon-based solvent such as n-pentane, isopentane, n-hexane, isohexane, n-heptane, isoheptane, 2,2,4-trimethyl pentane, n-octane, isooctane, cyclohexane, and methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, and n-amylnaphthalene.

In some embodiments, the organic solvent may be selected from alcohol-based solvents, ketone-based solvents, ester-based solvents, and any combinations thereof. In some embodiments, the organic solvent may be selected from 4-methyl-2-pentaneol (MIBC), propylene glycol monomethyl ether, propylene glycol monoethyl ether, propylene glycol monomethyl ether acetate, ethyl lactate, cyclohexanone, and a combination thereof.

### <Other Components>

The resist composition may further include a surfactant, a crosslinking agent, a leveling agent, a colorant, or a combination thereof, if necessary.

The resist composition may further include a surfactant to improve coatablity, developability, and the like. Examples of the surfactant may include a nonioinc surfactant such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, and polyethyleneglycol distearate. Any commercially available product or a synthetic product may be used as the surfactant. Examples of the commercially available product may include KP341 (manufactured by Shin-Etsu Chemical Co., Ltd.), Polyflow No. 75 and Polyflow No. 95 (manufactured by Kyoeisha Chemical Co., Ltd.), Eftop EF301, Eftop EF303, and Eftop EF352 (manufactured by Mitsubishi Materials Electronic Chemicals Co., Ltd.), MEGAFACE (registered trademark) F171, MEGAFACE F173, R40, R41, and R43 (manuf)ctured by DIC Corporation), Fluorad (registered trademark) FC430, Fluorad FC431 (manufactured by 3M Co., Ltd.), AsahiGuard AG710 (manufactured by AGC Co., Ltd.), and Surflon (registered trademark) S-382, Surflon SC-101, Surflon SC-102, Surflon SC-103, Surflon SC-104, Surflon SC-105, and Surflon SC-106 (manufactured by AGC Seimi Chemical Co., Ltd).

The surfactant may be included in a range of about 0 parts by weight to about 20 parts by weight based on 100 parts by weight of the organometallic compound. The surfactant may be used alone or any mixture of two or more different surfactants may also be used.

A method of preparing the resist composition is not particularly limited, and the resist composition may be prepared by, for example, mixing the organometallic compound and optional components added as needed. Temperature or time is not particularly limited during mixing. If necessary, filtration may be performed after mixing.

### [Pattern Formation Method]

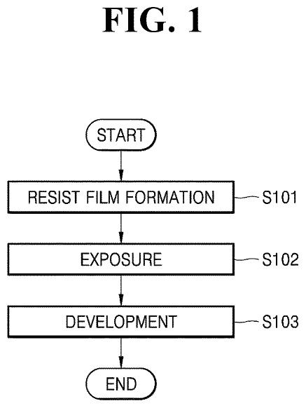

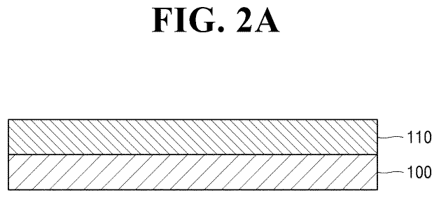

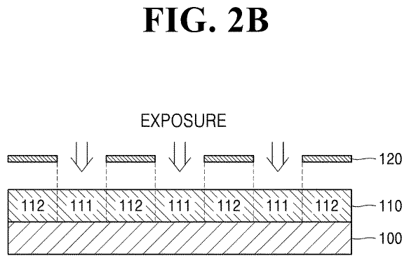

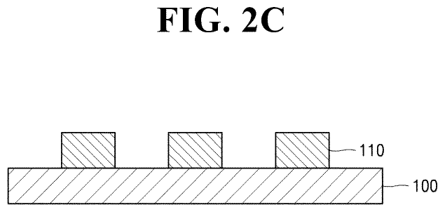

Hereinafter, a pattern formation method according to embodiments will be described in more detail with reference to FIGS. 1 and 2A to 2C. FIG. 1 is a flowchart illustrating a pattern formation method according to embodiments, and FIG. 2A to 2C are side cross-sectional views illustrating a pattern formation method according to embodiments. Hereinafter, a pattern formation method using a negative resist composition will be described by way of example, but the embodiment is not limited thereto.

Referring to FIG. 1, a pattern formation method includes forming a resist film by applying a resist composition (S101), exposing at least one portion of the resist film to high-energy rays (S102) to provide an exposed resist film, and developing the exposed resist film using a developer (S103). These operations may be omitted or may be performed in a different order, if necessary.

First, a substrate 100 is prepared. The substrate 100 may be a semiconductor substrate such as a silicon substrate and a germanium substrate, or may include glass, quartz, ceramic, copper, or the like. In some embodiments, the substrate 100 may include compounds of Groups 3 to 5, such as GaP, GaAs, and GaSb.

A resist film 110 may be formed on the substrate 100 by applying the resist composition thereto to a desired thickness using a coating method. If necessary, the resist film 110 may be heated (pre-baked, PB) to remove the organic solvent remaining therein. In some embodiments, by heating the resist film 110, radicals may be generated, and then through exposure, the radicals may chemically combine to form a crosslink.

As the coating method, spin coating, dipping, roller coating, or other common coating methods may be used. Among them, spin coating may particularly be used. The resist film 110 having a desired thickness may be formed by adjusting viscosity, concentration, and/or spin speed of the resist composition. In an embodiment, the resist film 110 may have a thickness of about 10 nm to about 300 nm. In an embodiment, the resist film 110 may have a thickness of about 30 nm to about 200 nm.

A lower limit of a pre-baking temperature may be 60° C. or higher, or 80° C. or higher. In an embodiment, an upper limit of the pre-baking temperature may be 150° C. or less or 140° C. or lower. A lower limit of a pre-baking time may be 5 seconds or more, or, 10 seconds or more. An upper limit of the pre-baking time may be 600 seconds or less, or, 300 seconds or less.

Before applying the resist composition to the substrate 100, a film to be etched (not shown) may be formed on the substrate 100. The film to be etched may refer to a film onto which an image is transferred from a resist pattern and converted into a pattern. In an embodiment, the film to be etched may be formed to include, for example, an insulating material such as a silicon oxide, a silicon nitride, and a silicon oxynitride. In some embodiments, the film to be etched may be formed to include a conductive material such as a metal, a metal nitride, a metal silicide, and a metal silicide nitride film. In some embodiments, the film to be etched may be formed to include a semiconductor material such as polysilicon.

In an embodiment, an anti-reflection film may further be formed on the substrate 100 to maximize efficiency of the resist. The anti-reflection film may be an organic or inorganic anti-reflection film.

In an embodiment, a protective film may further be formed on the resist film 110 to reduce effects of alkaline impurities included during a process. In an embodiment, in the case of performing immersion lithography, a protective film for immersion lithography may be formed on the resist film to avoid direct contact between an immersion medium and the resist film 110.

Subsequently, at least one portion of the resist film 110 may be exposed to high-energy rays. For example, high-energy rays having passed through a mask 120 may reach at least one portion of the resist film 110. Therefore, the resist film 110 may have an exposed region 111 and a non-exposed region 112.

Although not limited to a specific theory, radicals are generated in the exposed portion 111 by exposure, and chemical bonds are formed between the radicals, which may change the physical properties of the resist composition.

The light exposure is performed by irradiating high-energy rays through a mask having a particular pattern using a liquid such as water as a medium, if necessary. Examples of the high-energy rays may include electromagnetic waves such as ultraviolet rays, deep ultraviolet rays, extreme ultraviolet (EUV) rays (wavelength of 13.5 nm), X-rays, and γ-rays; and charged particle beams such as electron beams and a particle beams. Irradiation of these high-energy rays can be collectively referred to as “exposure to light.”

Various light sources may be used for the exposure. For example, a light source emitting laser beams in the UV range, such as a KrF excimer laser (wavelength of 248 nm), an ArF excimer laser (wavelength of 193 nm), and an F₂ excimer laser (wavelength of 157 nm), a light source emitting harmonic laser beams in the far ultraviolet or vacuum ultraviolet range by converting wavelengths of laser beams received from a solid laser light source (YAG or semiconductor laser), and a light source emitting electron beams or EUVs may be used. During exposure, a mask corresponding to a desired pattern is commonly used. However, in the case of using electron beams as a light source for exposure, exposure may be directly performed without using a mask.

In the case of using extreme ultraviolet rays as the high-energy rays, an integral dose of the high-energy rays may be 2000 mJ/cm² or less or 500 mJ/cm² or less. In an embodiment, in the case of using electron beams as the high-energy rays, the integral dose may be 5000 μC/cm² or less or 1000 μC/cm² or less.

In an embodiment, post exposure baking (PEB) may be performed after exposure. A lower limit of a PEB temperature may be 50° C. or higher, or 80° C. or higher. An upper limit of the PEB temperature may be 250° C. or lower, or 200° C. or lower. A lower limit of a PEB time may be, 5 seconds or more or 10 seconds or more. An upper limit of the PEB time may be 600 seconds of less, or 300 seconds or less.

The resist film 110 which has been exposed may be developed using a developer. The non-exposed region 112 may be removed by being washed away by the developer, and the exposed portion 111 remains without being washed away by the developer.

Examples of the developer may include an alkaline developer and a developer including an organic solvent (hereinafter, also referred to as an “organic developer”). A developing method may be dipping, puddling, spraying, dynamic approach, or the like. A developing temperature may be, for example, from about 5° C. to about 60° C., and a developing time may be, for example, from about 5 seconds to about 300 seconds.

Examples of the alkaline developer may include an alkaline aqueous solution including at least one alkaline compound dissolved therein such as sodium hydroxide, potassium hydroxide, sodium carbonate, sodium silicate, sodium metasilicate, aqueous ammonia, ethylamine, n-propylamine, diethylamine, di-n-propyl amine, triethylamine, methyldiethylamine, ethyldimethylamine, triethanolamine, tetramethyl ammonium hydroxide (TMAH), pyrrole, piperidine, choline, 1,8-diazabicyclo [5.4.0]-7-undecene (DBU), and 1,5-diazabicyclo [4.3.0]-5-nonene (DBN). The alkaline developer may further include a surfactant.

A lower limit of an amount of the alkaline compound contained in the alkaline developer may be 0.1 wt % or more or 0.5 wt % or more, or 1 wt % or more. In an embodiment, an upper limit of the amount of the alkaline compound contained in the alkaline developer may be 20 wt % or less, or 10 wt % or less, or 5 wt % or less.

For example, the organic solvent contained in the organic developer may be the same as those described above in the <Organic Solvent> section of the [Resist Composition]. In an embodiment, the organic developer may be n-butyl acetate (nBA), propylene glycol methyl ether (PGME), propylene glycol methyl ether acetate (PGMEA), γ-butyrolactone (GBL), isopropanol (IPA), etc. The organic developer may include more organic acids such as acetic acid, formic acid, citric acid, etc.

Regarding the organic developer, a lower limit of the amount of the organic solvent may be 80 wt % or more, 90 wt % or more, 95 wt % or more, or 99 wt % or more.

The organic developer may include a surfactant. In an embodiment, the organic developer may include a trace amount of moisture. In an embodiment, development may be stopped during developing by replacing the organic developer with a different type of solvent.

The resist pattern may further be washed after the developing. Ultrapure water, a ringing solution, and the like may be used during washing. The rinsing solution is not particularly limited as long as the resist pattern is not dissolved therein, and any solution including a common organic solvent may be used. For example, the rinsing solution may be an alcohol-based solvent or an ester-based solvent. After washing, the rinsing solution remaining on the substrate and the pattern may be removed. In an embodiment, in the case of using ultrapure water, water remaining on the substrate and the pattern may be removed.

In an embodiment, the developer may be used alone or any combination of two or more different developers may also be used.

After the resist pattern is formed as described above, a pattered wiring substrate may be obtained by etching. Any etching methods well known in the art such as dry etching using plasma gas, and wet etching using an alkaline solution, a copper (II) chloride solution, or a ferric chloride solution may be used.

After forming the resist pattern, plating may be performed. A plating method is not particularly limited, and, for example, copper plating, solder plating, nickel plating, and gold plating may be used therefor.

The resist pattern remaining after etching may be stripped off using an organic solvent. Examples of the organic solvent may be, but are not limited to, propylene glycol monomethylether acetate (PGMEA), propylene glycol monomethylether (PGME), and ethyl lactate (EL). A peeling method is not particularly limited, but may be, for example, immersing and spraying. In an embodiment, a wiring substrate on which the resist pattern is formed may be a multi-layered wiring substrate or may have a small-diameter through hole.

In an embodiment, the wiring substrate may be formed by a method including forming a resist pattern, depositing a metal in a vacuum, and melting the resist pattern using a solution, i.e., a lift-off method.

Hereinafter, the disclosure will be described in more detail according to the following examples and comparative examples. However, the following examples are merely presented as non-limiting examples of the disclosure, and the scope of the disclosure is not limited thereto.

### EXAMPLES

### Synthesis Example 1: Synthesis of OM-A

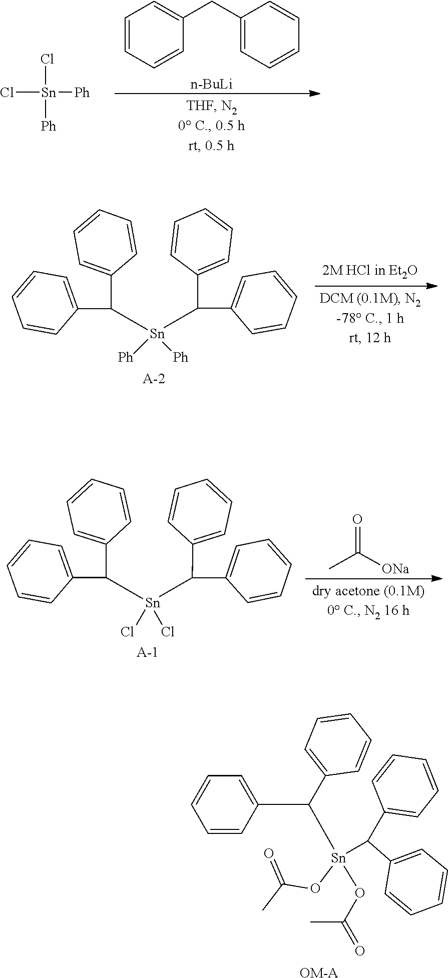

### (1) Synthesis of A-2

Diphenylmethane (4.89 g, 29.1 mmol) was added to an N₂-substituted 2-neck round bottom flask and diluted with THF (30 ml). n-BuLi (2.5 M in hexane, 29.1 mmol) was added dropwise thereto at −78° C., and then stirred at 0° C. for 0.5 hours. Dichlorodiphenylstannane (5 g, 14.5 mmol) was added to a vial and diluted with THF (28 ml, total THF (58 ml, 0.25 M)). The solution in the vial was added thereto dropwise to the round bottom flask at −78° C., stirred for 0.5 hours, then heated to room temperature and stirred again for 0.5 hours. After confirming the completion of the reaction, the solvent was removed, filtered with silica/celite, and purified by column chromatography (ethylacetate (EA):n-hexane (EA 5 v %), thereby obtaining A-2 (6.8 g, 77%).

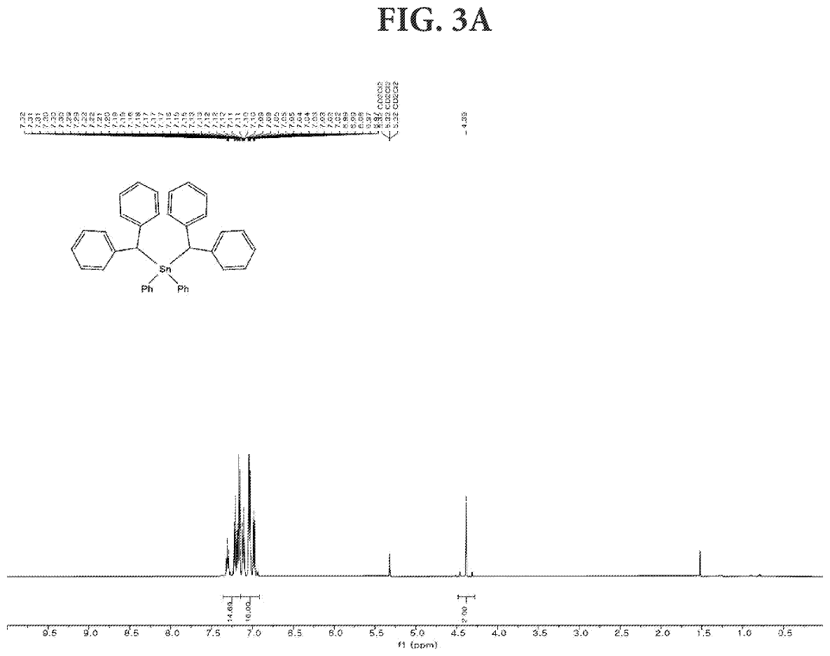

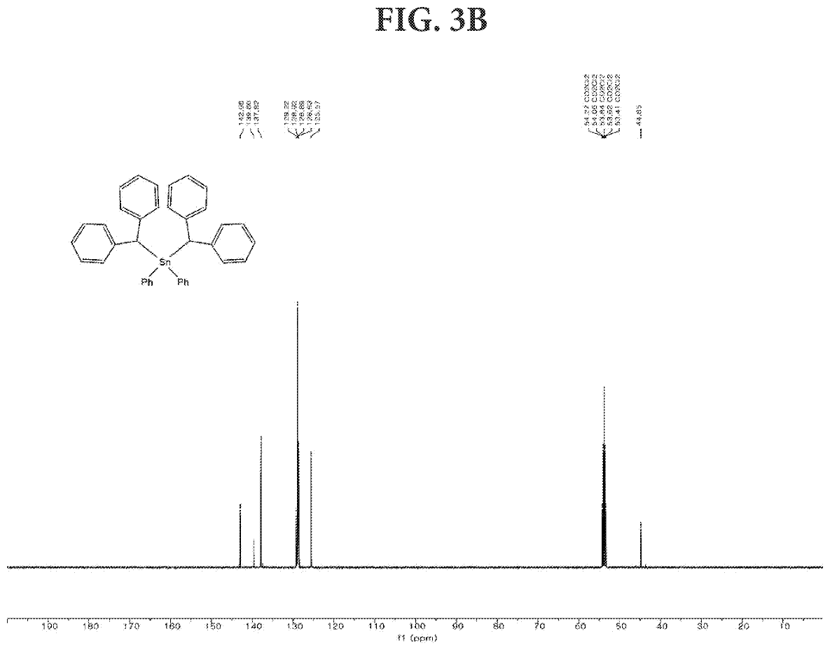

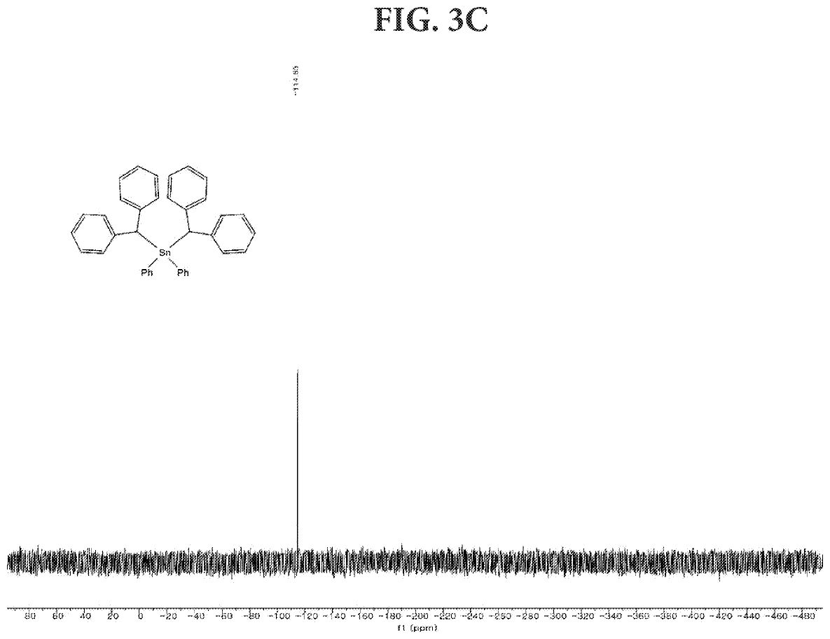

FIGS. 3A to 3C are diagrams showing ¹H-NMR data, ¹³C-NMR data and ¹¹⁹Sn-NMR data of A-2, respectively.

### (2) Synthesis of A-1

A-2 (6.2 g, 10.2 mmol) was placed in a round bottom flask and substituted with N₂. After dilution with dichloromethane (102 ml, 0.1 M), 2M HCl in Et₂O solution (15.3 ml, 30.67 mmol) was added dropwise thereto at −78° C. After stirring at −78° C. for 1 hour, the temperature was raised to room temperature and then stirred for 12 hours of a reaction. The solvent was removed therefrom, and the precipitate was obtained by washing with methyl t-butyl ether:n-hexane (5 ml:100 ml), and then dried under vacuum to obtain A-1 (4.3 g, 80%).

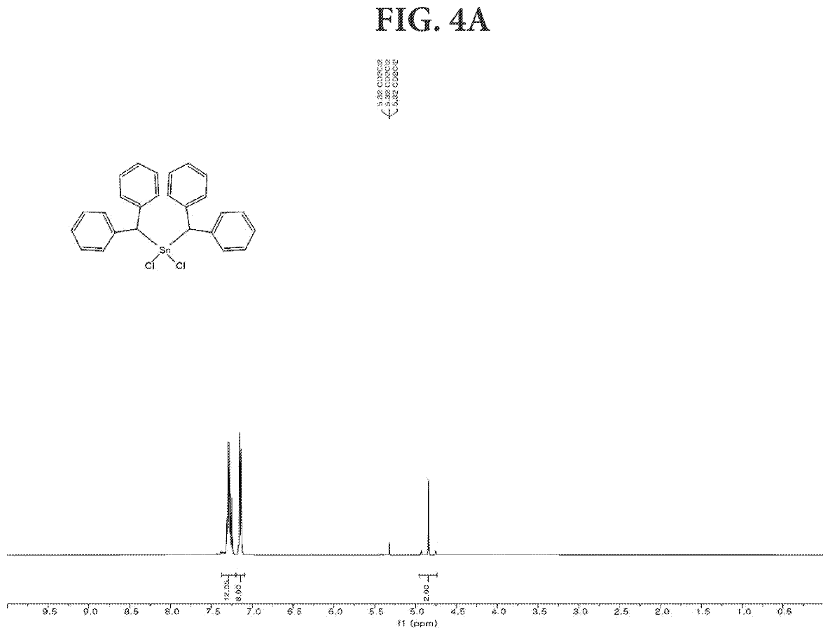

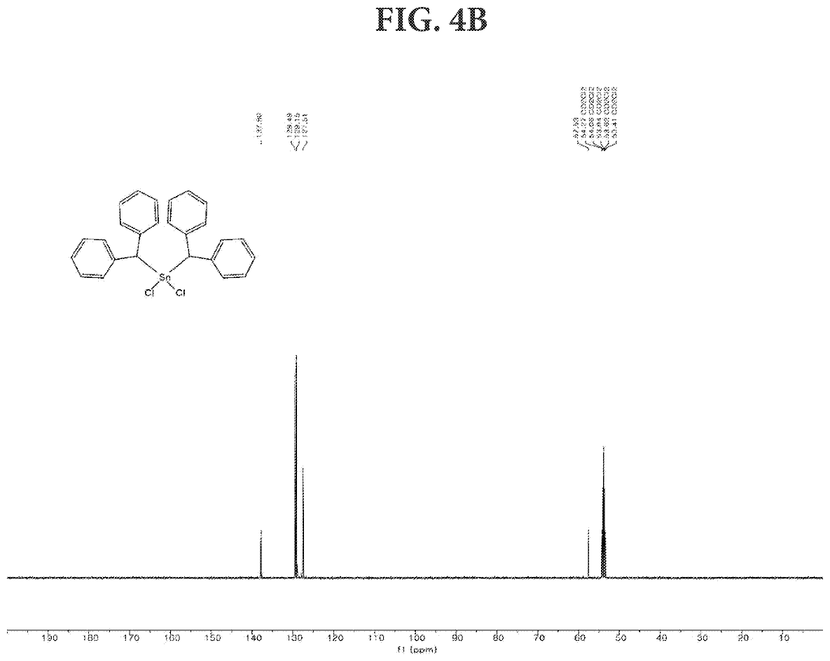

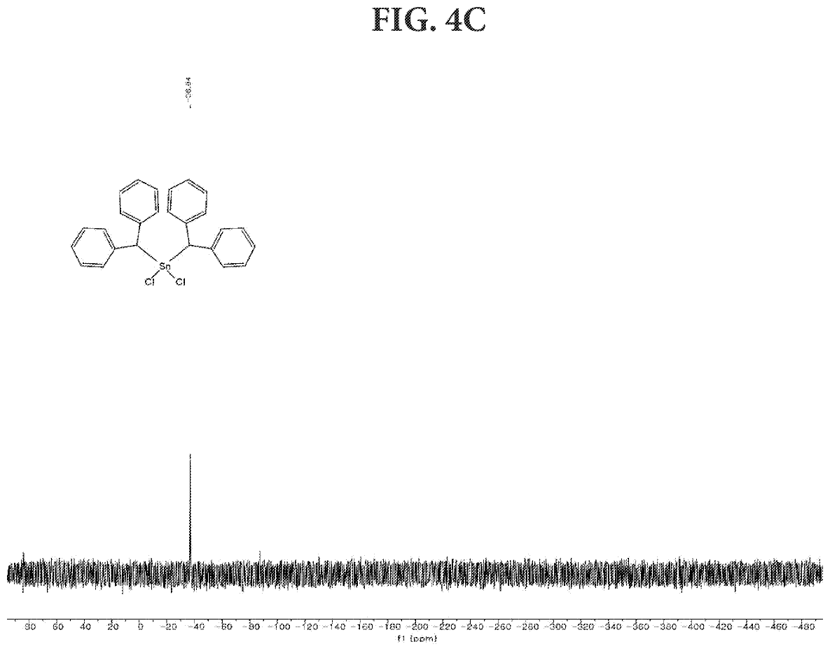

FIGS. 4A to 4C are diagrams showing ¹H-NMR data, ¹³C-NMR data and ¹¹⁹Sn-NMR data of A-1, respectively.

### (3) Synthesis of OM-A

A-1 (1.0 g, 1.91 mmol) was placed in a round bottom flask and substituted with N₂. After dilution with acetone (19 ml, 0.1 M), sodium acetate (0.31 g, 3.82 mmol) was added thereto at 0° C. After reacting at 0° C. for 16 hours, filtering was performed using celite. The solvent was removed, followed by recrystallisation (methyl t-butyl ether:n-hexane=3 ml:30 ml). After filtering, the precipitate was dried under vacuum to obtain OM-A (0.54 g, 50%).

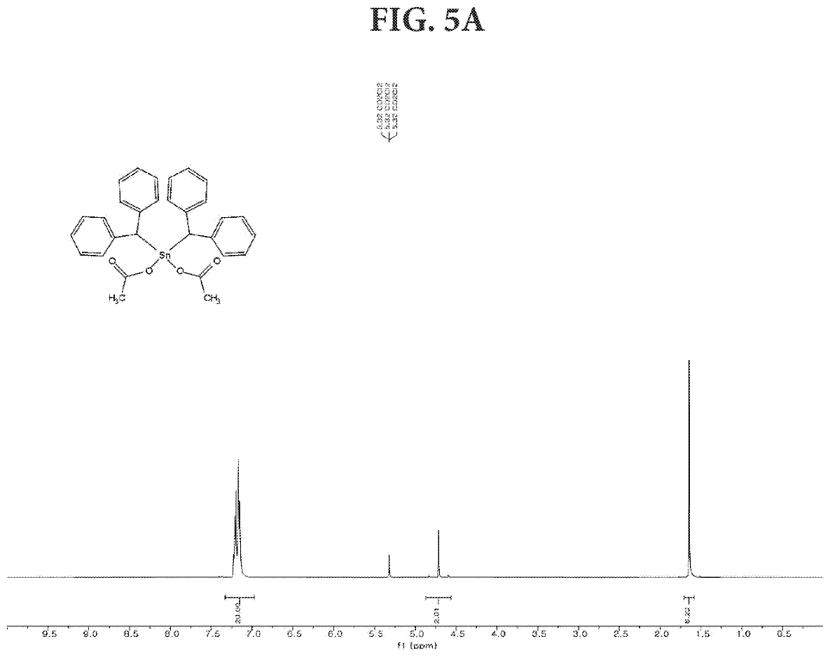

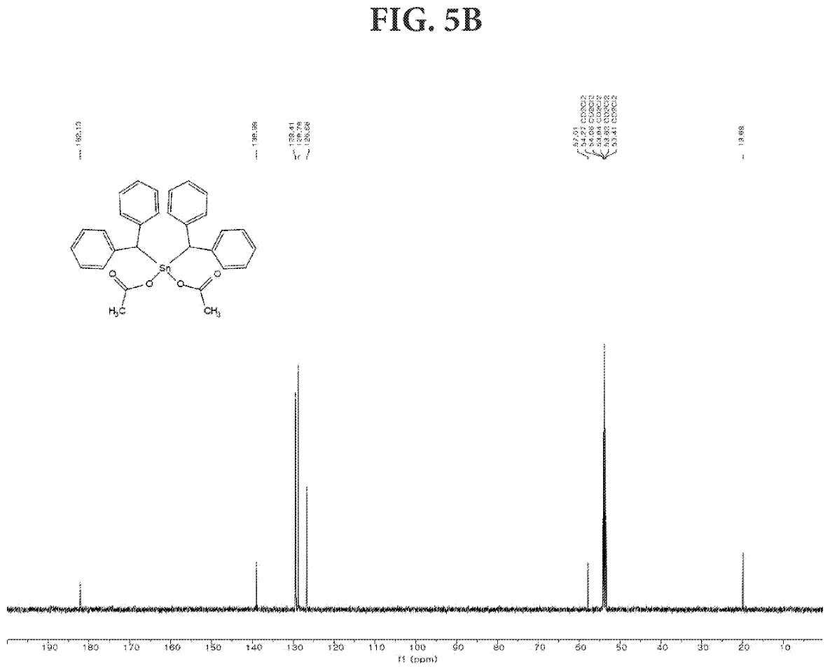

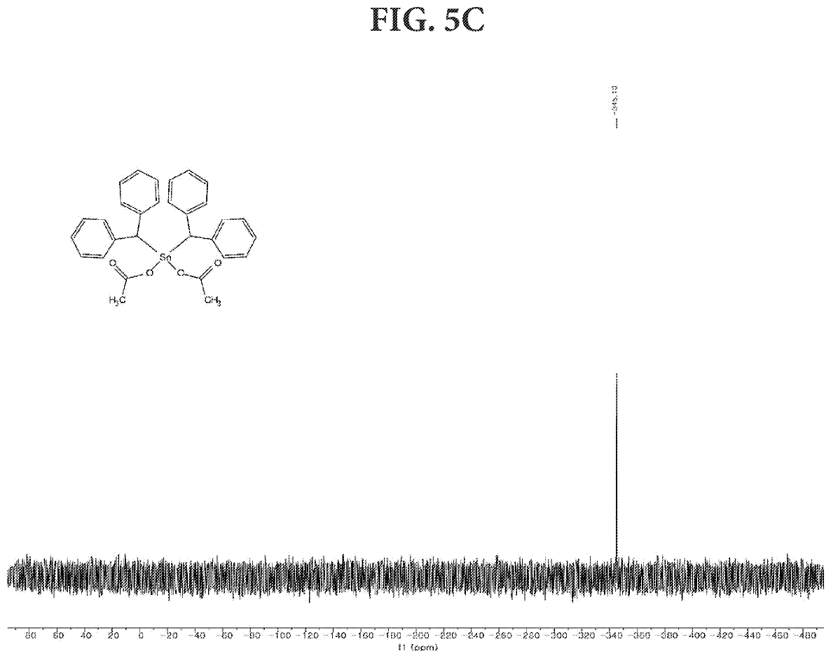

FIGS. 5A to 5C are diagrams showing ¹H-NMR data, ¹³C-NMR data and ¹¹⁹Sn-NMR data of OM-A, respectively.

### Synthesis Example 2: Synthesis of OM-B

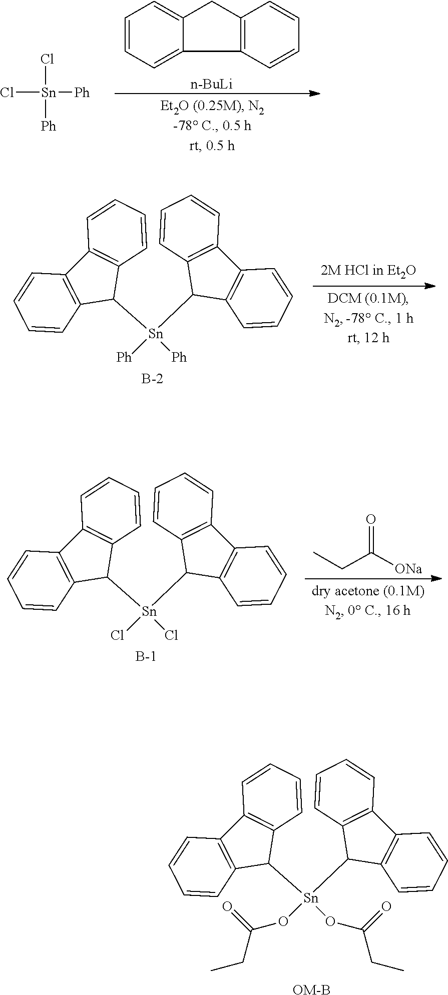

### (1) Synthesis of B-2

Fluorene (8.31 g, 50.0 mmol) was added to an N₂-substituted 2-neck round bottom flask and diluted with THF (30 ml). n-BuLi (2.5 M in hexane, 20 ml, 50 mmol) was added dropwise thereto at −78° C., and then stirred at 0° C. for 0.5 hours. Dichlorodiphenylstannane (8.60 g, 25.0 mmol) was added to a vial and diluted with THF (50 ml, total THF 100 ml (0.25 M)). The solution in the vial was added thereto dropwise to the round bottom flask at −78° C., stirred for 0.5 hours, then heated to room temperature and stirred again for 0.5 hours. After confirming the completion of the reaction, the solvent was removed, filtered with silica/celite, and purified by column chromatography (dichloromethane (DCM):n-hexane (DCM 10 v %)), thereby obtaining B-2 (12.1 g, 80%).

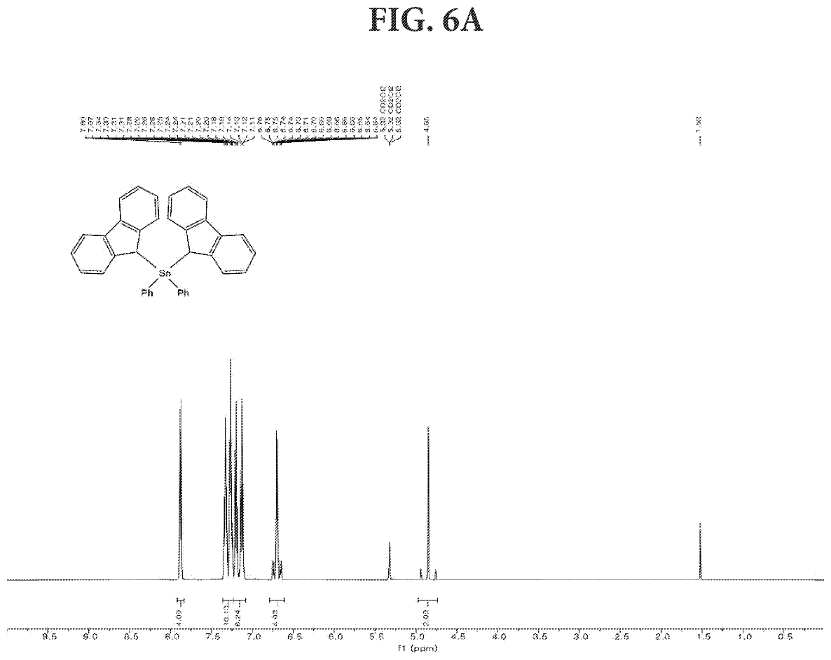

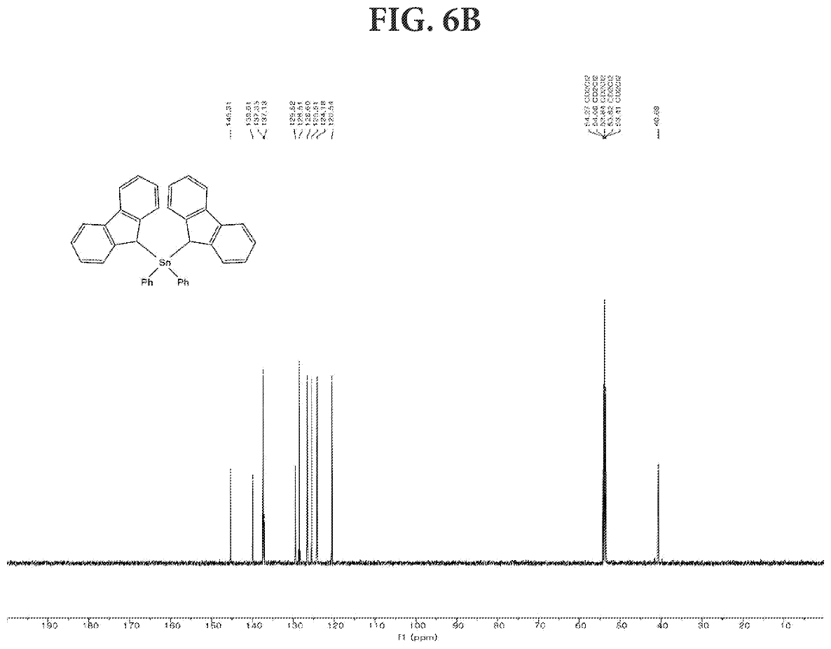

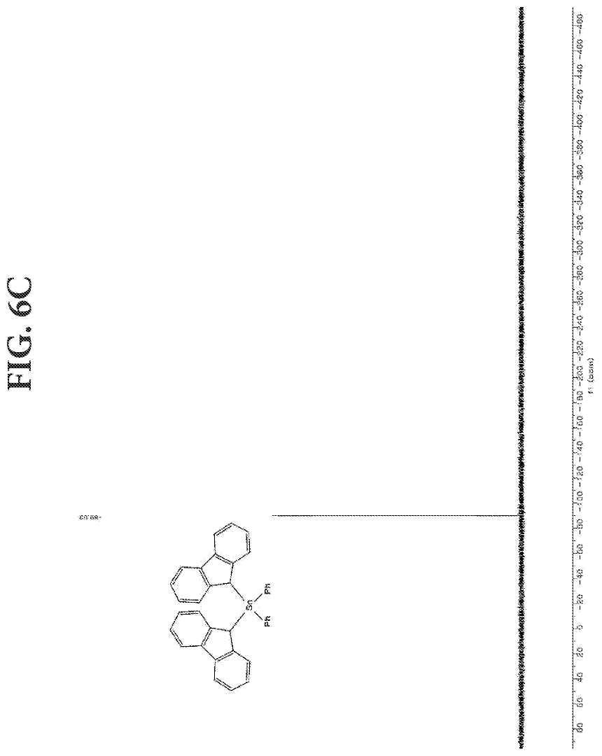

FIGS. 6A to 6C are diagrams showing ¹H-NMR data, ¹³C-NMR data and ¹¹⁹Sn-NMR data of B-2, respectively.

### (2) Synthesis of B-1

B-2 (12.0 g, 20.0 mmol) was placed in a round bottom flask and substituted with N₂. After dilution with dichloromethane (200 ml, 0.1 M), 2M HCl in Et₂O solution (30 ml, 60 mmol) was added dropwise thereto at −78° C. After stirring at −78° C. for 1 hour, the temperature was raised to room temperature and then stirred for 12 hours of a reaction. The solvent was removed, washed with n-hexane to obtain a precipitate, and the precipitate was dried under vacuum to obtain B-1 (8.8 g, 85%).

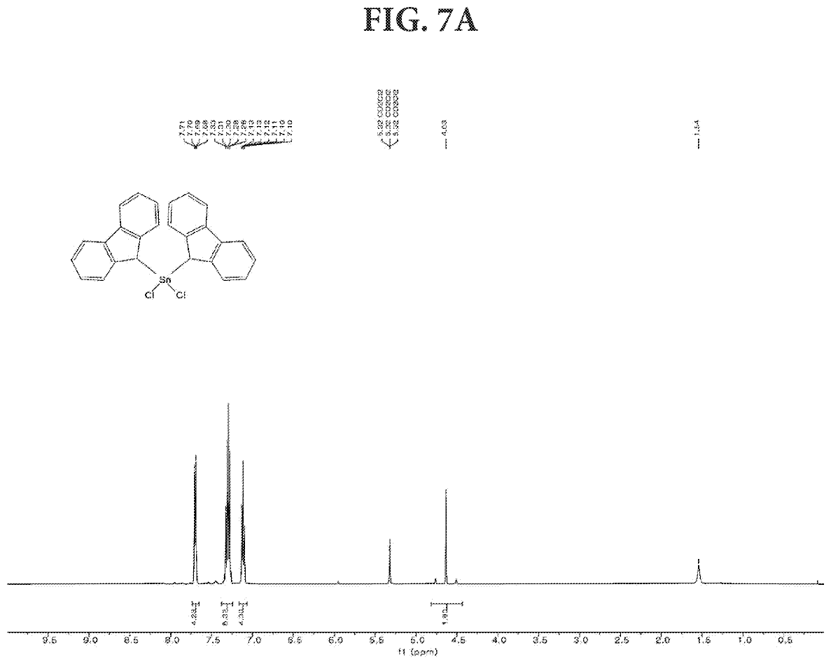

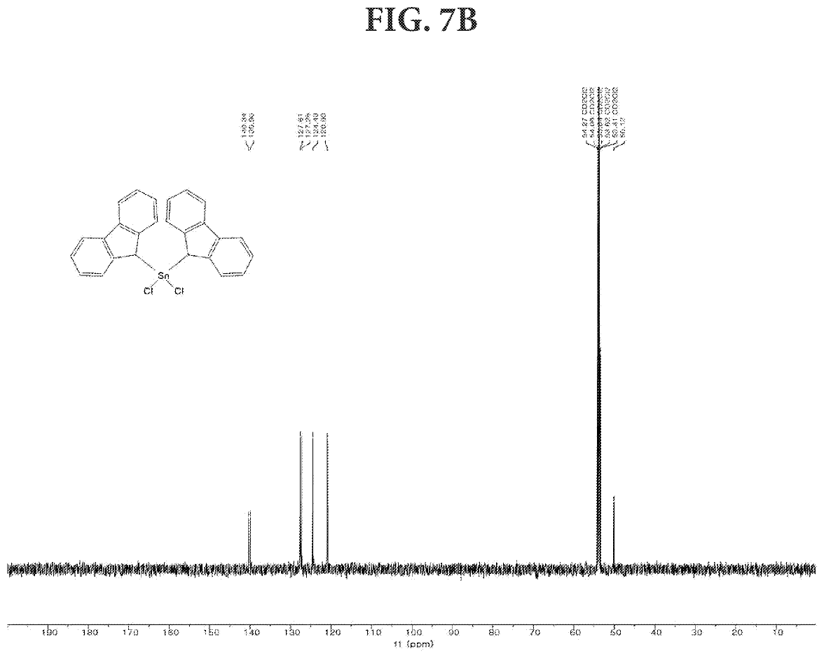

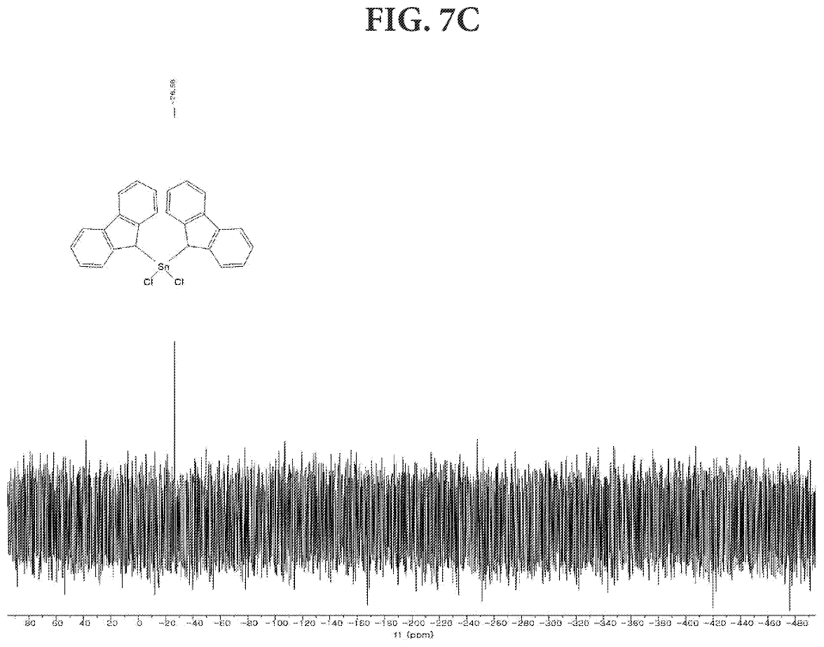

FIGS. 7A to 7C are diagrams showing ¹H-NMR data, ¹³C-NMR data and ¹¹⁹Sn-NMR data of B-1, respectively.

### (3) Synthesis of OM-B

B-1 (1.5 g, 2.88 mmol) was placed in a round bottom flask and substituted with N₂. After dilution with acetone (29 ml, 0.1 M), sodium propionate (0.55 g, 5.77 mmol) was added thereto at 0° C. After reacting at 0° C. for 16 hours, filtering was performed using celite. The solvent was removed and then recrystallisation was carried out (dichloromethane:n-hexane=5 ml:100 ml). After filtering and drying under vacuum, OM-B (1.30 g, 76%) was obtained.

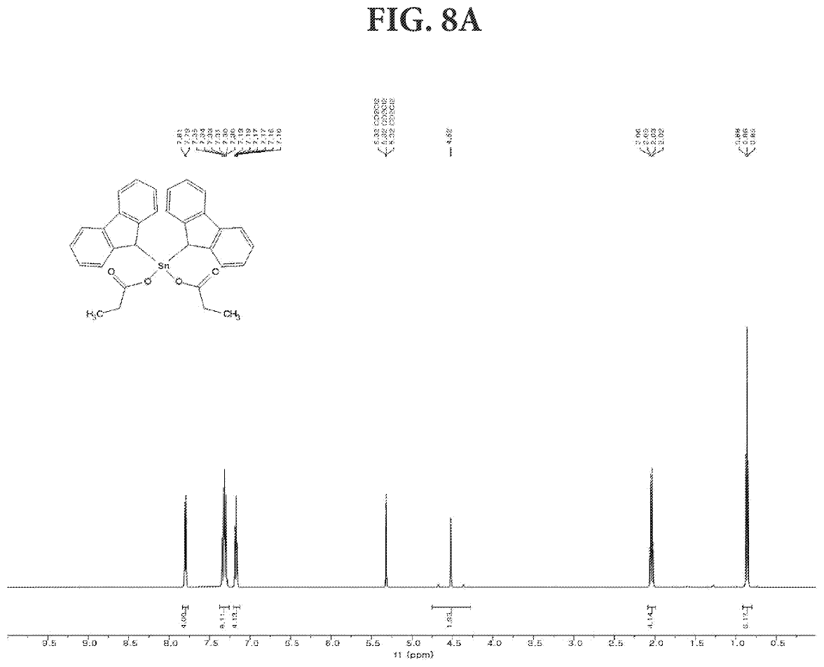

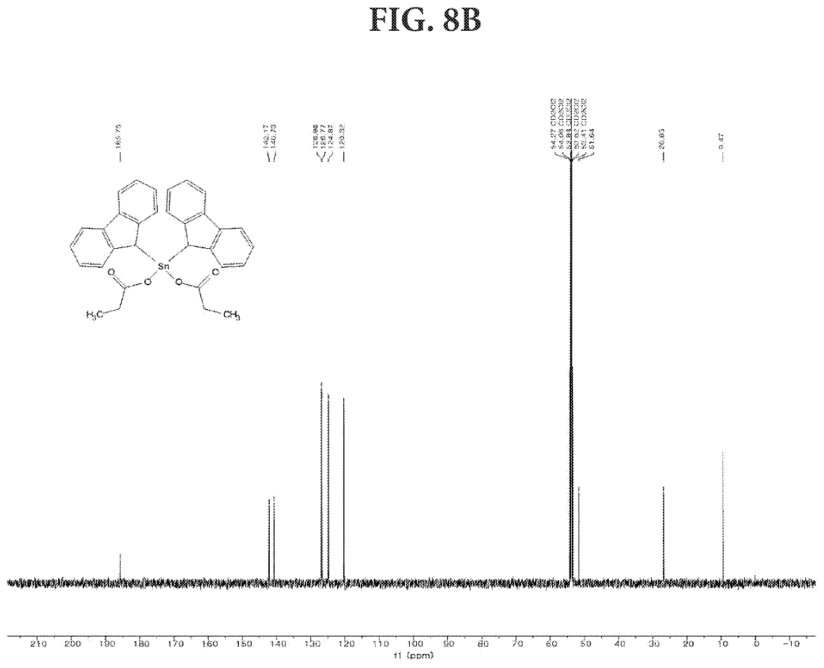

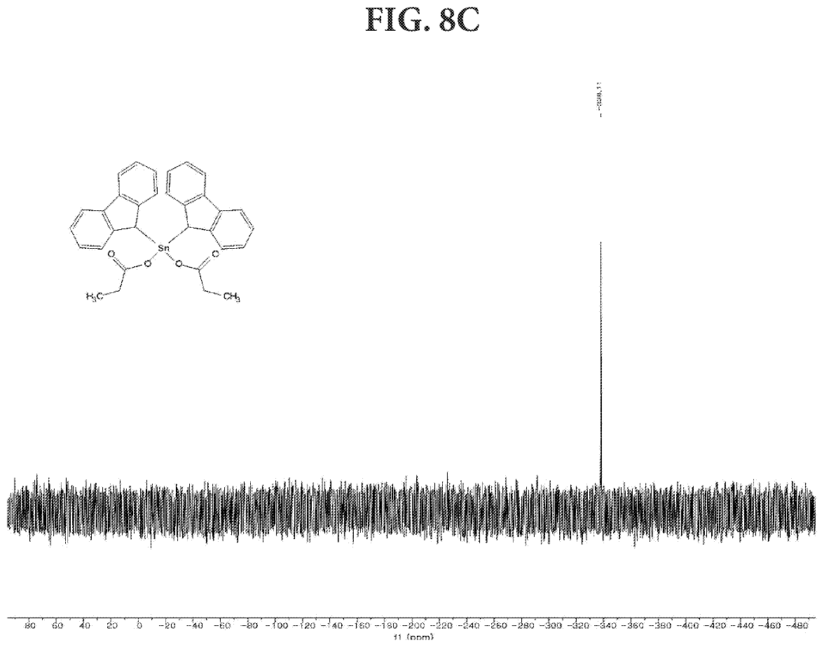

FIGS. 8A to 8C are diagrams showing ¹H-NMR data, ¹³C-NMR data and ¹¹⁹Sn-NMR data of OM-B, respectively.

### Evaluation Example: Thin Film Developing Evaluation

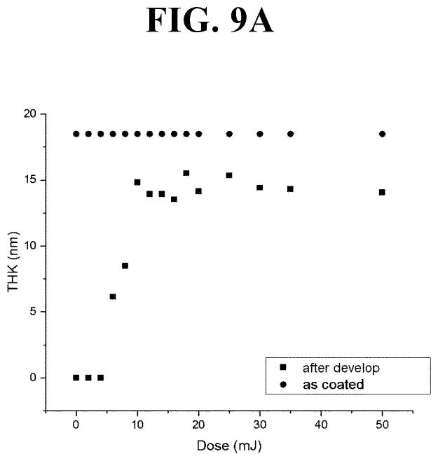

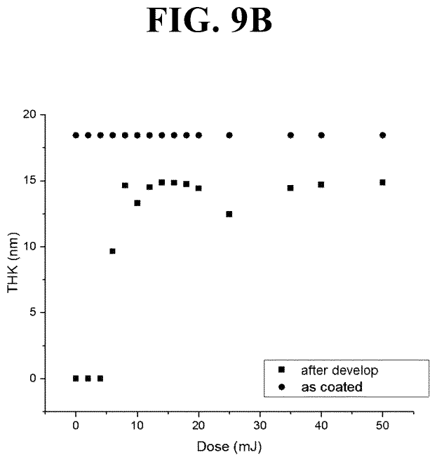

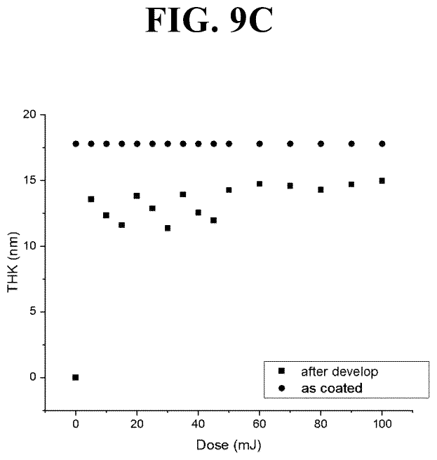

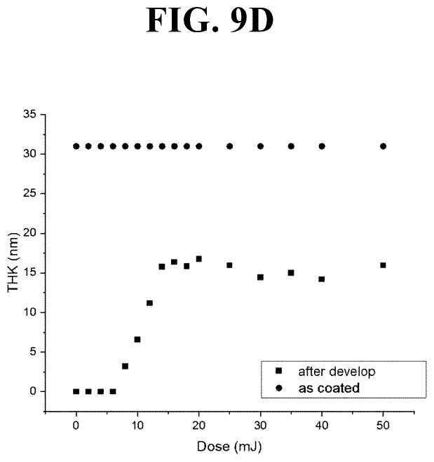

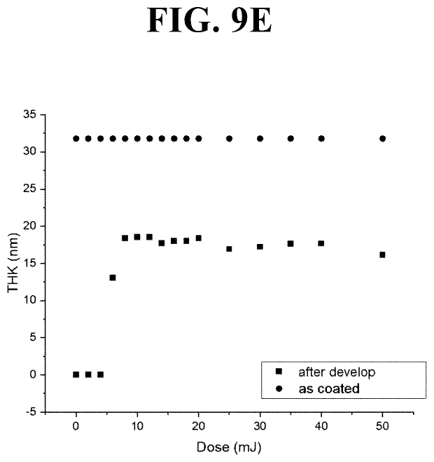

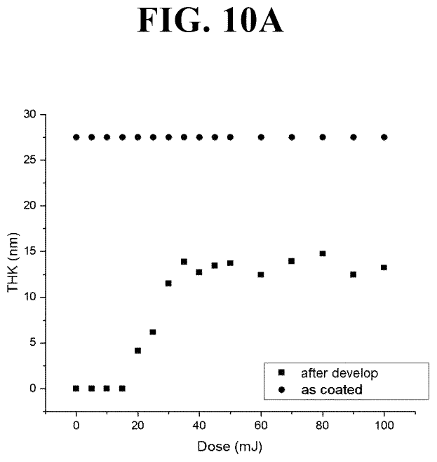

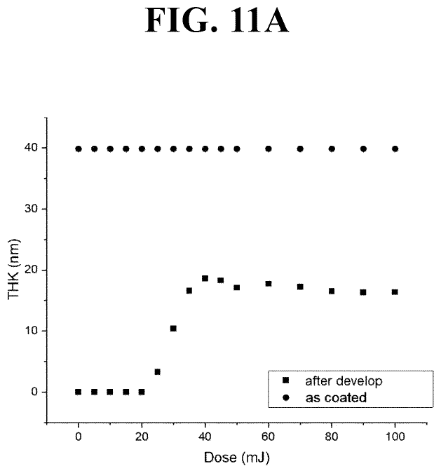

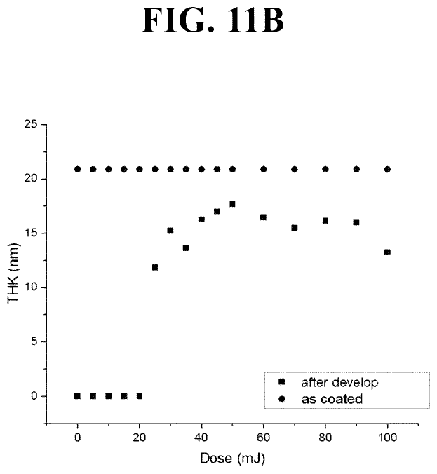

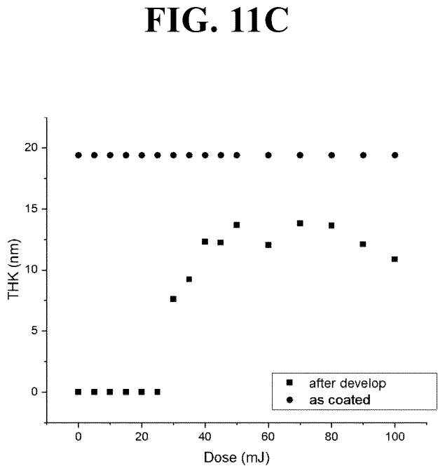

For example, the organometallic compound synthesized in each of Synthesis Example 1 and 2 was dissolved at 2 wt % in the casting solvent listed in Table 1 below. A silicon wafer with a diameter of 4 inches was treated with O₂ plasma for 30 minutes, spin-coated with the casting solution at 1200 rpm for 1 minute, and then dried (PAB) at 120° C. for 1 minute to produce a film with the initial thickness shown in Table 1 below. Then, a 3.5 mm thick zig (4×4) with rectangular holes (1 cm×1 cm) was placed thereon, and each hole was exposed to DUV at a wavelength of 254 nm with a dose of 0 mJ/cm² to 50 mJ/cm² or 0 mJ/cm² to 100 mJ/cm², and dried (PEB) at 120° C. to 160° C. for 1 minute. The dried film was soaked in a PGMEA solution containing 2% by weight of acetic acid as a developer, and then soaked at 25° C. for 60 seconds. The thickness of the remaining film was measured and shown in Table 2 and FIGS. 9A to 9E, 10A and 11A to 11C below. In FIGS. 9A to 9E, 10A and 11A to 11C, “as-coated” is reference data for samples which were not treated with a developer, and “after develop” is data for samples which were treated with a developer. In an embodiment, in order to compare the effect of the ligand, Eth and E1 of Examples 1-3, 2-1, and Comparative Examples 1 to 3 were compared and are shown in Tables 3 and 4 below.

TABLE 2

| | | | | Initial | | | | |
|---|---|---|---|---|---|---|---|---|
| | Organometallic | | PAB | thickness | PEB | E_{TH} | E₁ | |
| | compound | Casting solvent | (° C.) | (nm) | (° C.) | (mJ) | (mJ) | Graph |
| Example 1-1 | OM-A | Cyclohexanone | 120 | 19 | 120 | 5 | 10 | FIG. |
| | | | | | | | | 9A |
| Example 1-2 | OM-A | Cyclohexanone | 120 | 18 | 140 | 5 | 8 | FIG. |
| | | | | | | | | 9B |
| Example 1-3 | OM-A | Cyclohexanone | 120 | 18 | 160 | 3 | 5 | FIG. |
| | | | | | | | | 9C |
| Example 1-4 | OM-A | Cyclopentanone | 120 | 29 | 120 | 7 | 14 | FIG. |
| | | | | | | | | 9D |
| Example 1-5 | OM-A | Cyclopentanone | 120 | 32 | 140 | 5 | 8 | FIG. |
| | | | | | | | | 9E |
| Example 2-1 | OM-B | Cyclohexanone | 120 | 28 | 160 | 18 | 33 | FIG. |
| | | | | | | | | 10A |
| Comparative | C-1 | Cyclopentanone | 120 | 40 | 160 | 23 | 40 | FIG. |
| Example 1 | | | | | | | | 11A |
| Comparative | C-2 | Ethyl lactate | 120 | 21 | 160 | 23 | 35 | FIG. |
| Example 2 | | | | | | | | 11B |
| Comparative | C-3 | Ethyl lactate | 120 | 19 | 160 | 28 | 40 | FIG. |
| Example 3 | | | | | | | | 11C |

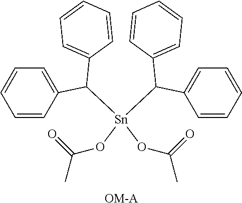

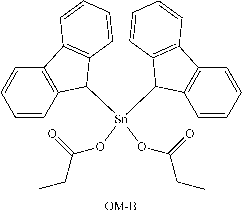

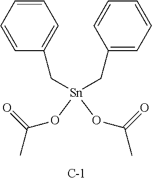

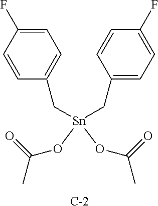

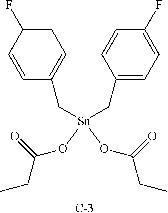

TABLE 3

| | | | Eₜₕ of | Eₜₕ of | |
|---|---|---|---|---|---|
| | | Comparative | Exam- | Comparative | Ratio of |
| No. | Example | Example | ple | Example | change |
| Compar- | Example | Comparative | 3 | 23 | 87% |
| ison 1 | 1-3 | Example 1 | | | decrease |
| Compar- | Example | Comparative | 3 | 23 | 87% |
| ison 2 | 1-3 | Example 2 | | | decrease |
| Compar- | Example | Comparative | 18 | 28 | 36% |
| ison 3 | 2-1 | Example 3 | | | decrease |

TABLE 4

| | | | E₁ of | E₁ of | |
|---|---|---|---|---|---|
| | | Comparative | Exam- | Comparative | Ratio of |
| No. | Example | Example | ple | Example | change |
| Compar- | Example | Comparative | 5 | 40 | 88% |
| ison 4 | 1-3 | Example 1 | | | decrease |
| Compar- | Example | Comparative | 5 | 35 | 86% |
| ison 5 | 1-3 | Example 2 | | | decrease |
| Compar- | Example | Comparative | 33 | 40 | 18% |
| ison 6 | 2-1 | Example 3 | | | decrease |

In Tables 2 to 4, Eₜₕ refers to the exposure amount at the point when a thin film begins to harden, and E₁ refers to the exposure amount at the saturation point where the thickness of a thin film no longer increases.

Referring to Table 2, it can be seen that Examples 1-1 and 1-2 show the same level of contrast as Examples 1-4 and 1-5. That is, it can be seen that a resist composition including an organometallic compound according to an embodiment of the disclosure can be advantageous in appropriately controlling the temperature of the pattern formation process as desired.

Referring to Table 2, it can be seen that Eₜₕ and E₁ of Examples 1-1 to 1-5 and 2-1 are smaller than Eₜₕ and E₁ of Comparative Examples 1 to 3. This result shows that the resist composition of Examples 1-1 to 1-5 and 2-1 have improved photosensitivity compared to the resist compositions of Comparative Examples 1 to 3.

Referring to Tables 3 and 4, as the structure of the ligand represented by *—C(Q₁₁)_{b11}(R₁₁)_{(3-b11)}, *—C(Q₁₂)_{b12}(R₁₂)_{(3-b12)}*—C(Q₁₃)_{b13}(R₁₃)_{(3-b13)} and/or *—C(Q₁₄)_{b14}(R₁₄)_{(3-b14)} of the organometallic compound according to an embodiment of the disclosure, Eₜₕ and E₁ are changed. Specifically, it can be seen that Example 1-3 using an organometallic compound having 2 or more Q₁₁, exhibits significantly reduced Eₜₕ and E₁ compared to Comparative Example 1 and Comparative Example 2, and similarly, Example 2-1 also show significantly reduced Eₜₕ and E₁ compared to Comparative Example 3.

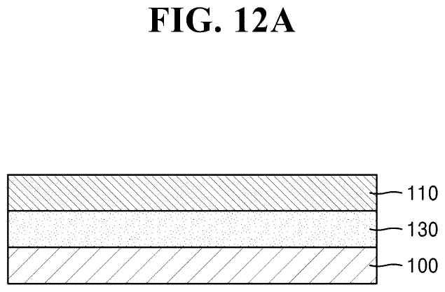

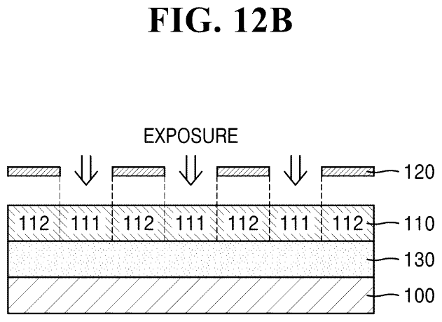

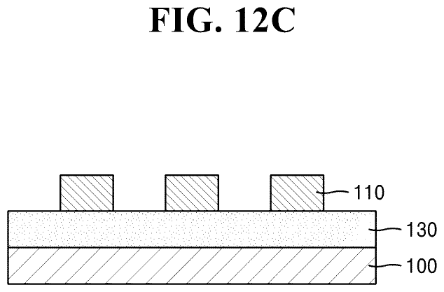

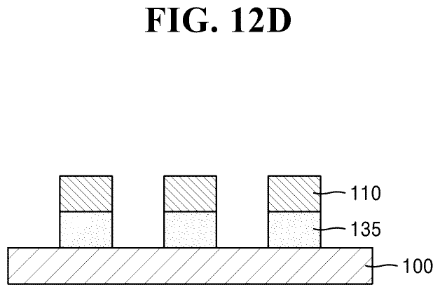

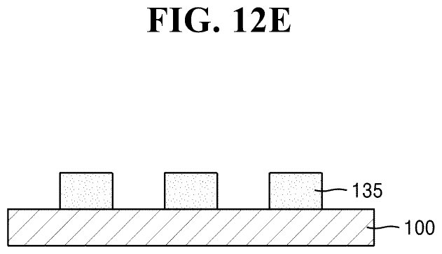

FIGS. 12A to 12E are side cross-sectional views illustrating a method of forming a patterned structure according to an embodiment.

Referring to FIG. 12A, a material layer 130 may be formed on the substrate 100 before forming a resist film 110 on the substrate 100. The resist film 110 may be formed on top of the material layer 130. The material layer 130 may include an insulating material (e.g., silicon oxide, silicon nitride), a semiconductor material (e.g., silicon), a metal (e.g., copper). In some embodiments, the material layer 130 may be a multi-layer structure. A material of the material layer 130 may be different than a material of the substrate 100. The resist film 110 may include a resist composition according to example embodiments and may have a thickness of about 10 nm to about 300 nm or about 30 nm to about 200 nm.

Referring to FIG. 12B, the resist film 110 may be exposed with high energy rays through a mask 120, after which the resist film 110 may include exposed regions 111 and unexposed regions 112.

Referring to FIG. 12C, the exposed resist film 110 may be developed using a developer (e.g., developing solution). The exposed portion 111 may remain without being washed away by the developer, whereas the non-exposed portion 112 may be washed away by the developer.

Referring to FIG. 12D, exposed areas of the material layer 130 may be etched using the resist pattern 110 as a mask to form a material pattern 135 on the substrate 100.

Referring to FIG. 12E, the resist pattern 110 may be removed.

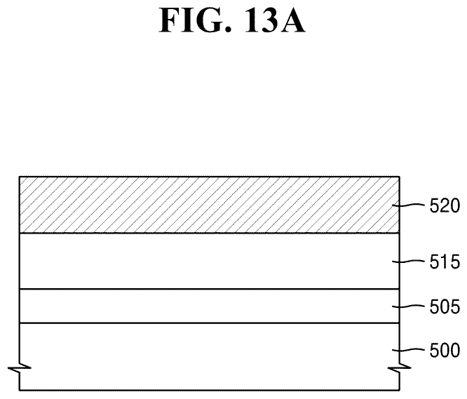

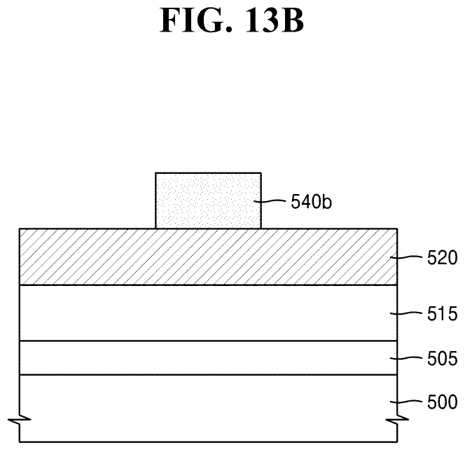

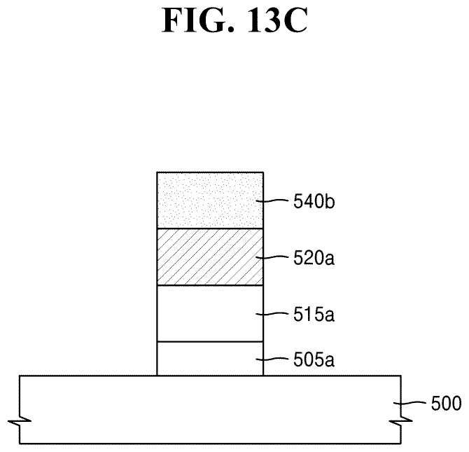

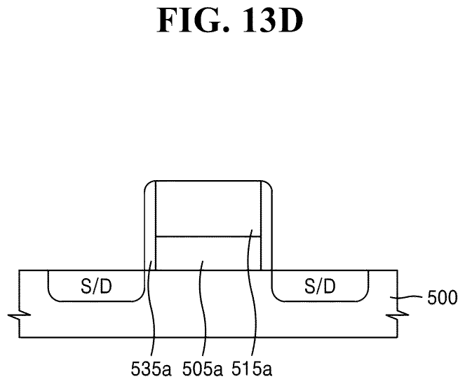

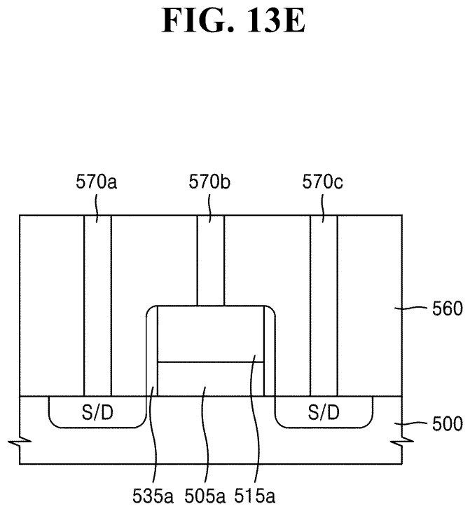

FIGS. 13A to 13E are side cross-sectional views illustrating a method of forming a semiconductor device according to an embodiment.

Referring to FIG. 13A, a gate dielectric 505 (e.g., silicon oxide) may be formed on a substrate 500. The substrate 500 may be a semiconductor substrate, such as a silicon substrate. A gate layer 515 (e.g., doped polysilicon) may be formed on the gate dielectric 505. A hardmask layer 520 may be formed on the gate layer 515.

Referring to FIG. 13B, a resist pattern 540b may be formed on the hardmask layer 520. The resist pattern 540b may be formed using a resist composition according to example embodiments. The resist pattern 540b may be formed from a resist composition according to an example embodiment.

Referring to FIG. 13C, the gate layer 515 and the gate dielectric 505 may be etched to form a hardmask pattern 520a, a gate electrode pattern 515a, and a gate dielectric pattern 505a.

Referring to FIG. 13D, a spacer layer may be formed over the gate electrode pattern 515a and the gate dielectric pattern 505a. The spacer layer may be formed using a deposition process (e.g., CVD). The spacer layer may be etched to form spacers 535a (e.g., silicon nitride) on sidewalls of the gate electrode pattern 515a and the gate dielectric pattern 505a. After forming the spacers 535a, ions may be implanted into the substrate 500 to form source/drain impurity regions S/D.

Referring to FIG. 13E, an interlayer insulating layer 560 (e.g., oxide) may be formed on the substrate 500 to cover the gate electrode pattern 515a, gate dielectric pattern 505a, and spacers 535a. Then, electrical contacts 570a, 570b, and 570c may be formed in the interlayer insulating layer 560 to connect to the gate electrode 515a and the S/D regions. The electrical contacts may be formed of a conductive material (e.g., metal). Although not illustrated, a barrier layer may be formed between sidewalls of the interlayer insulating layer 560 and the electrical contacts 570a, 570b, and 570c. While FIGS. 5A to 5E illustrate an example of forming a transistor, inventive concepts are not limited thereto.

A resist composition according to one or more embodiments may be used in a patterning process to form other types of semiconductor devices.

According to the embodiments, a resist composition having improved sensitivity and providing a pattern with increased resolution may be provided.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An organometallic compound represented by one of Formulae 1-1 to 1-4: 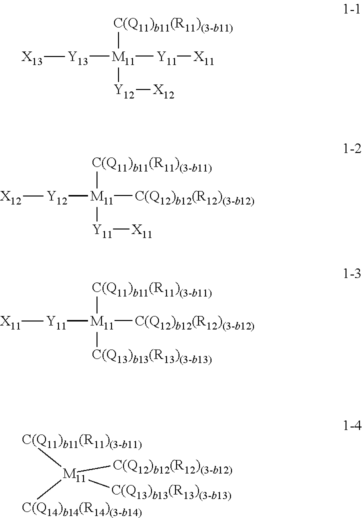
wherein, in Formulae 1-1 to 1-4,
M₁₁ is indium (In), tin (Sn), antimony (Sb), tellurium (Te), thallium (Tl), lead (Pb), bismuth (Bi), or polonium (Po),
Q₁₁ to Q₁₄ are each independently a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
b11 is 2 or 3,
b12 to b14 are each independently an integer from 0 to 3,
R₁₁ to R₁₄ are each independently hydrogen, deuterium, a halogen, a hydroxyl group, a cyano group, a nitro group, a carboxylic acid group, a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, or a substituted or unsubstituted C₁-C₃₀ heteroaryl group,
an adjacent two of Q₁₁ to Q₁₄ and R₁₁ to R₁₄ are optionally bonded to each other to form a condensed ring,
Y₁₁ to Y₁₃ are each independently O, O(C═O), S, S(C═O), NX₁₄, or N(C═O)X₁₄, and
X₁₁ to X₁₄ are each independently hydrogen, deuterium, or a linear, branched, or cyclic C₁-C₃₀ monovalent hydrocarbon group optionally including a hetero atom.

2. The organometallic compound of claim 1, wherein
a bond dissociation energy of a bond between M₁₁ and C of the organometallic compound is 30 kcal/mol or less.

3. The organometallic compound of claim 1, wherein
M₁₁ is In, Sn, or Sb.

4. The organometallic compound of claim 1, wherein
Q₁₁ to Q₁₄ are each independently selected from a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, and a C₁-C₃₀ heteroaryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof, and
R₁₁ to R₁₄ are each independently selected from: hydrogen; deuterium; a halogen; a hydroxyl group; a cyano group; a nitro group; a carboxylic acid group; and a C₁-C₃₀ alkyl group, a C₃-C₃₀ cycloalkyl group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, and a C₁-C₃₀ heteroaryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or a combination thereof.

5. The organometallic compound of claim 1, wherein
b12 is 2 or 3;
b13 is 2 or 3; or
b14 is 2 or 3.

6. The organometallic compound of claim 1, wherein
*—C(Q₁₁)_{b11}(R₁₁)_{(3-b11)} is represented by one of Formulae 2-11 to 2-14,
*—C(Q₁₂)_{b12}(R₁₂)_{(3-b12)} is represented by one of Formulae 2-21 to 2-30,
*—C(Q₁₃)_{b13}(R₁₃)_{(3-b13)} is represented by one of Formulae 2-31 to 2-40, and
*—C(Q₁₄)_{b14}(R₁₄)_{(3-b14)} is represented by one of Formulae 2-41 to 2-50: 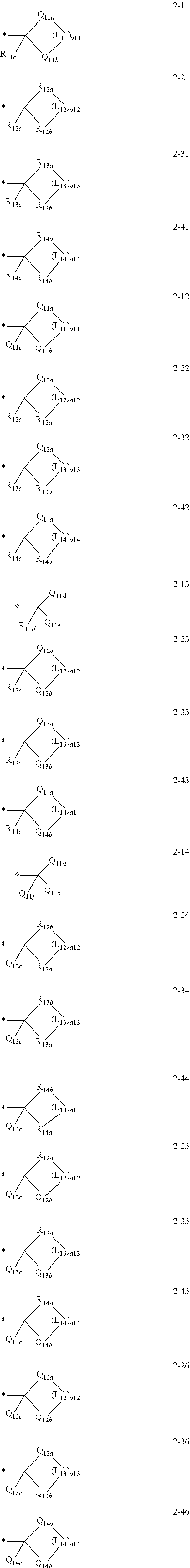 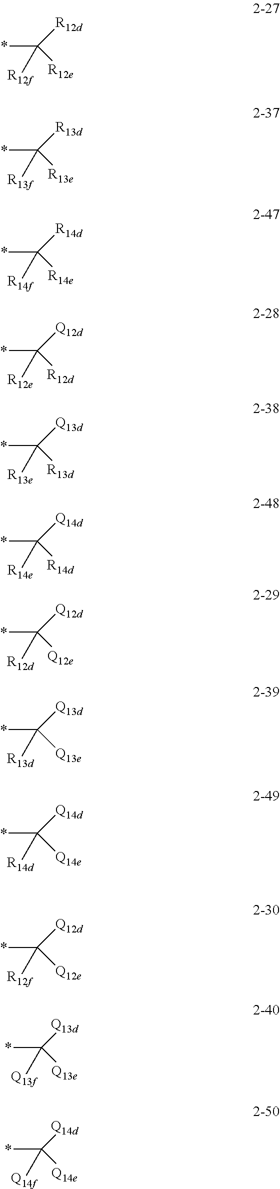
wherein, in Formulae 2-11 to 2-14 and 2-21 to 2-50,
Q₁₁ₐ to Q_{11f}, Q₁₂ₐ to Q_{12f}, Q₁₃ₐ to Q_{13f} and Q₁₄ₐ to Q_{14f} are the same definition as Q₁₁ in Formulae 1-1 to 1-4,
R_{11c}, R_{11d}, R₁₂ₐ to R_{12f}, R₁₃ₐ to R_{13f} and R₁₄ₐ to R_{14f} are the same definition as R₁₁ in Formulae 1-1 to 1-4,
L₁₁ to L₁₄ are each independently be a single bond, O, S, a C₁-C₁₀ alkylene group, or a C₂-C₁₀ alkenylene group,
a11 to a14 are each independently be an integer from 1 to 3, and
* is a binding site with an adjacent atom.

7. The organometallic compound of claim 6, wherein
Q₁₁ₐ, Q_{11b}, Q₁₂ₐ, Q_{12b}, Q₁₃ₐ, Q_{13b}, Q₁₄ₐ, Q_{14b}, R₁₂ₐ, R_{12b}, R₁₃ₐ, R_{13b}, R₁₄ₐ, and R_{14b} are each independently a substituted or unsubstituted C₃-C₃₀ cycloalkenyl group, a substituted or unsubstituted C₃-C₃₀ heterocycloalkenyl group, a substituted or unsubstituted C₆-C₃₀ aryl group, or a substituted or unsubstituted C₁-C₃₀ heteroaryl group.

8. The organometallic compound of claim 1, wherein
*—C(Q₁₁)_{b11}(R₁₁)_{(3-b11)} is represented by one of Formulae 3-11 to 3-14,
*—C(Q₁₂)_{b12}(R₁₂)_{(3-b12)} is represented by one of Formulae 3-21 to 3-24,
*—C(Q₁₃)_{b13}(R₁₃)_{(3-b13)} is represented by one of Formulae 3-31 to 3-34, and
*—C(Q₁₄)_{b14}(R₁₄)_{(3-b14)} is represented by one of Formulae 3-41 to 3-44: 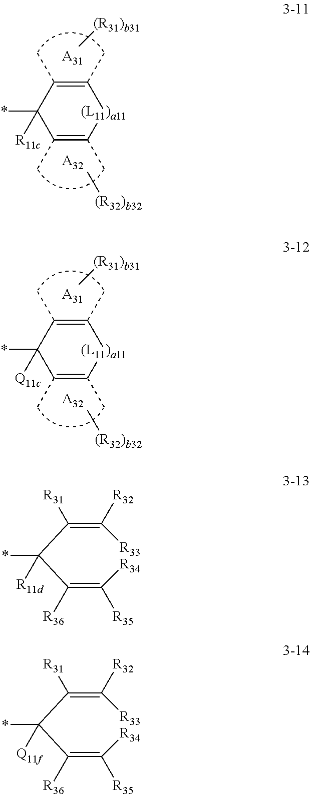 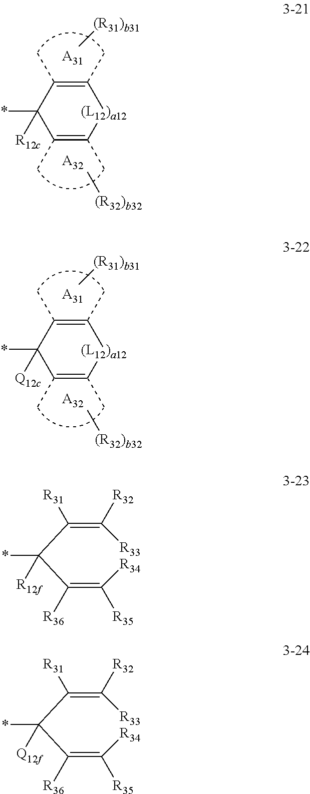 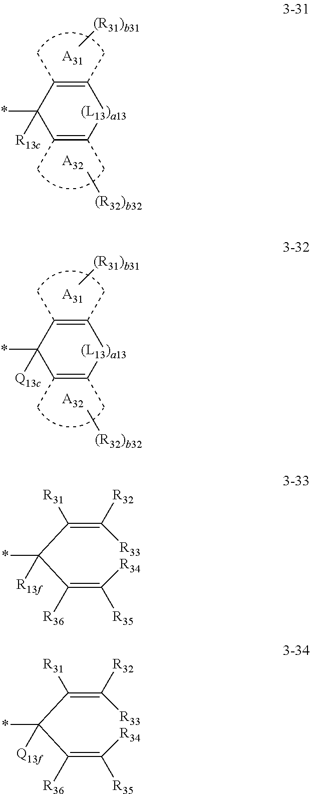 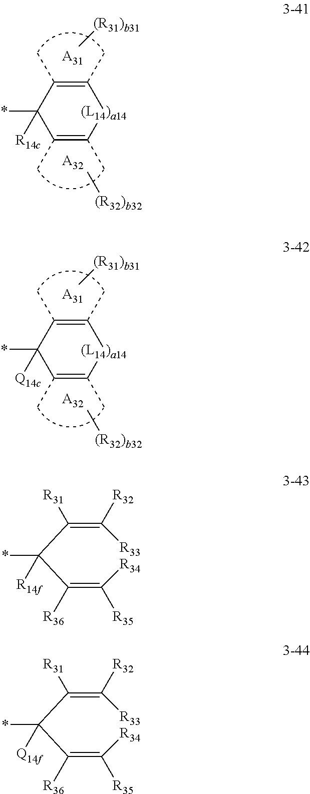
wherein, in Formulae 3-11 to 3-14, 3-21 to 3-24, 3-31 to 3-34, and 3-41 to 3-44,
Q_{11c}, Q_{11f}, Q_{12c}, Q_{12f}, Q_{13c}, Q_{13f}, Q_{14c}, and Q_{14f} are the same definition as Q₁₁ in Formulae 1-1 to 1-4,
R_{11c}, R_{11d}, R_{12c}, R_{12f}, R_{13c}, R_{13f}, R_{14c}, and R_{14f} are the same definition as Q₁₁ in Formulae 1-1 to 1-4,
L₁₁ to L₁₄ are each independently a single bond, O, S, a C₁-C₁₀ alkylene group, or a C₂-C₁₀ alkenylene group,
a11 to a14 are each independently an integer from 1 to 3, and
A₃₁ and A₃₂ are each independently a C₃-C₂₀ cycloalkenyl group, a C₃-C₂₀ heterocycloalkenyl group, a C₆-C₂₀ aryl group, or a C₁-C₂₀ heteroaryl group,
R₃₁ to R₃₆ are each independently deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₁₀ alkyl group, a C₁-C₁₀ halogenated alkyl group, a C₁-C₁₀ alkoxy group, a C₁-C₁₀ alkylthio group, a C₁-C₁₀ halogenated alkoxy group, a C₁-C₁₀ halogenated alkylthio group, a C₃-C₁₀ cycloalkyl group, a C₃-C₁₀ cycloalkoxy group, a C₃-C₁₀ cycloalkylthio group, a C₆-C₁₀ aryl group, a C₁-C₁₀ heteroaryl group, a C₆-C₁₀ aryloxy group, a C₆-C₁₀ arylthio group, a C₁-C₁₀ heteroaryloxy group, or a C₁-C₁₀ heteroarylthio group,
b31 and b32 are each independently an integer from 1 to 8, and
* is a binding site with an adjacent atom.

9. The organometallic compound of claim 1, wherein
X₁₁ to X₁₄ are each independently selected from: hydrogen; deuterium; and a C₁-C₂₀ alkyl group, a C₁-C₂₀ halogenated alkyl group, a C₃-C₂₀cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₂₀ aryl group, and a C₁-C₂₀ heteroaryl group, each unsubstituted or substituted with deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, or a combination thereof.

10. The organometallic compound of claim 1, wherein
the organometallic compound represented by one of Formulae 1-1 to 1-4 is represented by Formula 1-2,
*—C(Q₁₁)_{b11}(R₁₁)_{(3-b11)} is represented by one of Formulae 3-11 and 3-13, and
*—C(Q₁₂)_{b12}(R₁₂)_{(3-b12)} is represented by one of Formulae 3-21 to 3-23: 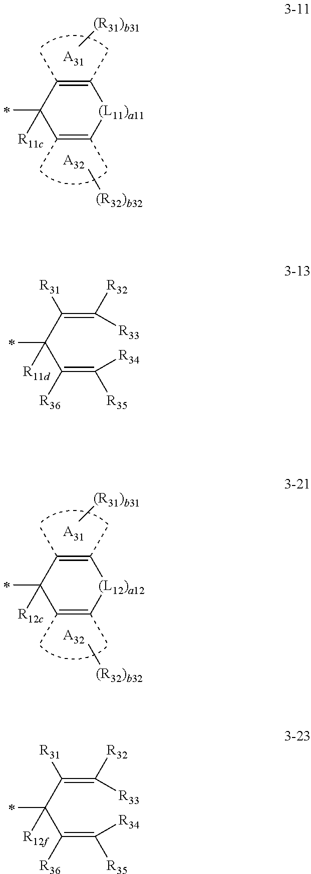
wherein, in Formulae 3-11, 3-13, 3-21 and 3-23,
R_{11c}, R_{11d}, R_{12c}, R_{12f} and R_{13c} are each the same definition as R₁₁ in Formulae 1-1 to 1-4,
L₁₁ and L₁₂ are each independently a single bond, O, S, a C₁-C₁₀ alkylene group, or a C₂-C₁₀ alkenylene group,
a11 to a12 are each independently an integer from 1 to 3, and
A₃₁ and A₃₂ are each independently a C₃-C₂₀ cycloalkenyl group, a C₃-C₂₀ heterocycloalkenyl group, a C₆-C₂₀ aryl group, or a C₁-C₂₀ heteroaryl group,
R₃₁ to R₃₆ are each independently deuterium, a halogen, a hydroxyl group, a cyano group, a nitro group, an amino group, a carboxylic acid group, an ether moiety, an ester moiety, a sulfonic acid ester moiety, a carbonate moiety, an amide moiety, a lactone moiety, a sultone moiety, a carboxylic anhydride moiety, a C₁-C₁₀ alkyl group, a C₁-C₁₀ halogenated alkyl group, a C₁-C₁₀ alkoxy group, a C₁-C₁₀ alkylthio group, a C₁-C₁₀ halogenated alkoxy group, a C₁-C₁₀ halogenated alkylthio group, a C₃-C₁₀ cycloalkyl group, a C₃-C₁₀ cycloalkoxy group, a C₃-C₁₀ cycloalkylthio group, a C₆-C₁₀ aryl group, a C₁-C₁₀ heteroaryl group, a C₆-C₁₀ aryloxy group, a C₆-C₁₀ arylthio group, a C₁-C₁₀ heteroaryloxy group, or a C₁-C₁₀ heteroarylthio group,
b31 and b32 are each independently an integer from 1 to 8, and
* is the binding site with a neighboring atom.

11. The organometallic compound of claim 1, wherein
the organometallic compound represented by one of Formulae 1-1 to 1-4 is selected from Group I:

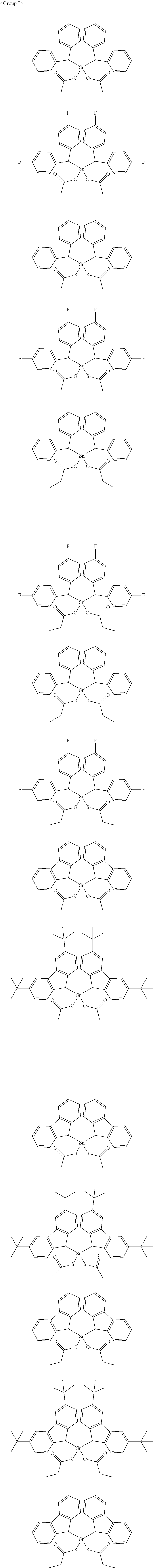

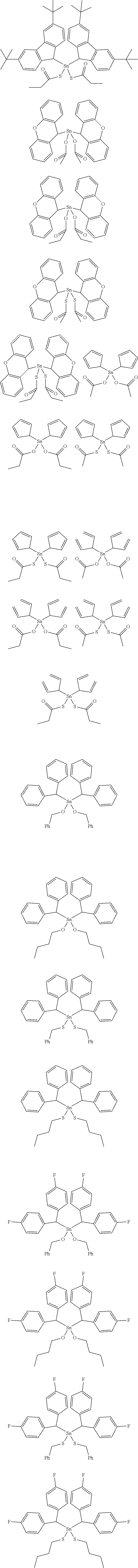

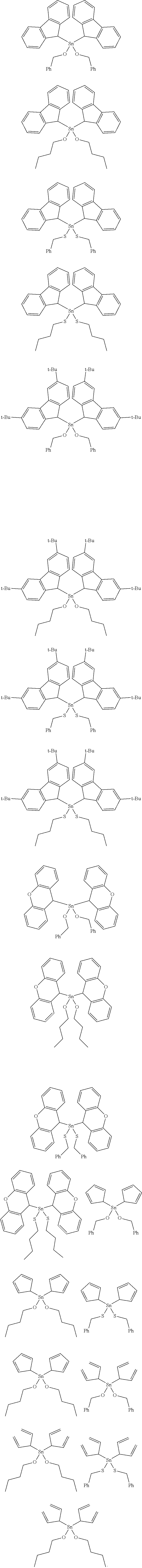

12. A resist composition comprising:
the organometallic compound of claim 1.

13. The resist composition of claim 12, wherein
the resist composition substantially does not comprise a photoacid generator.

14. The resist composition of claim 12, wherein
the resist composition substantially does not comprise a compound having a molecular weight of 1,000 or more.

15. The resist composition of claim 12, further comprising:
an organic solvent.

16. The resist composition of claim 15, wherein
the organic solvent comprises a protic organic solvent, an aprotic organic solvent, or a combination thereof.

17. A pattern formation method comprising:
forming a resist film by applying the resist composition of claim 12 on a substrate;
exposing at least a portion of the resist film to high-energy rays to provide an exposed resist film; and
developing the exposed resist film using a developer.

18. The pattern formation method of claim 17, wherein
the exposing is performed by irradiating the resist film using at least one of ultraviolet rays, deep ultraviolet rays (DUV), extreme ultraviolet rays (EUV), X-rays, γ-rays, electron beams (EBs), or α-rays.

19. The pattern formation method of claim 17, wherein
a chemical bond is formed between molecules of the organometallic compound by the exposing at least the portion of the resist film.

20. The pattern formation method of claim 17, wherein
the exposed resist film comprises an exposed portion and a non-exposed portion, and
in the developing, the non-exposed portion is removed.
